(19) United States
(12) Patent Application Publication
(10) Pub. No.: US 2026/0287789 A1
(43) Pub. Date: Sep. 24, 2026

(54) LENS COMPOSITION, DISPLAY PANEL, AND ELECTRONIC DEVICE

(71) Applicant: Samsung Display Co., Ltd., Yongin-si (KR)

(72) Inventors: Jihye Lim, Yongin-si (KR); Hyunsook Kim, Yongin-si (KR); Changwoo Lee, Yongin-si (KR)

(21) Appl. No.: 19/436,806

(22) Filed: Dec. 30, 2025

(30) Foreign Application Priority Data
Mar. 19, 2025 (KR) 10-2025-0035519

(51) Int. Cl. G02B 1/04; G02B 1/111; H10K 59/80

(52) U.S. Cl. CPC G02B 1/041; G02B 1/111; H10K 59/879

(57) ABSTRACT

A display panel, a lens composition for use in the display panel, and an electronic device including the display panel are disclosed. The display panel may include a plurality of light-emitting elements on a glass substrate, an encapsulation layer disposed or provided on the plurality of light-emitting elements and sealing the plurality of light-emitting elements, and a lens layer disposed or provided on the encapsulation layer and including a plurality of lens parts spaced and/or apart (e.g., spaced apart or separated) from each other. The lens layer may include a lens composition including a base resin including a cardo-based resin having a cardo-based moiety structure and having a refractive index of about 1.5 or more, an acid anhydride-based compound, a silane-based coupling compound, an acidic compound, and an oxime-based photoinitiator.

### CROSS-REFERENCE TO RELATED APPLICATION

The present application claims priority to and the benefit of Korean Patent Application No. 10-2025-0035519, filed on Mar. 19, 2025, in the Korean Intellectual Property Office, the entire disclosure of which is incorporated herein by reference.

### BACKGROUND

### 1. Field

One or more embodiments of the present disclosure relate to a lens composition for use in a display panel, a display panel, and an electronic device including the display panel.

### 2. Description of the Related Art

With the development of technologies, mobile electronic devices are widely used. In addition to portable electronic devices, such as mobile phones, mobile electronic devices including head-mounted displays (HMDs) that allow users to experience augmented reality (AR) or virtual reality (VR), are under development.

Such electronic devices include display panels to support one or more suitable functions, for example, providing visual information, such as images or videos, to users. As other parts to drive display panels have been miniaturized, the proportion occupied by display panels in electronic devices has been gradually increased.

### SUMMARY

One or more aspects of embodiments of the present disclosure are directed toward a lens composition to improve or enhance display quality and a display panel and an electronic device each utilizing the lens composition. However, this is only an example, and the scope of the present disclosure is not limited thereby.

Additional aspects of embodiments will be set forth in part in the description which follows and, in part, will be apparent from the description, or may be learned by practice of the presented embodiments of the disclosure.

According to one or more embodiments, a display panel includes a plurality of light-emitting elements on a glass substrate, an encapsulation layer disposed or provided on the plurality of light-emitting elements and sealing the plurality of light-emitting elements, and a lens layer disposed or provided on the encapsulation layer and including a plurality of lens parts spaced and/or apart (e.g., spaced apart or separated) from each other, wherein the lens layer includes a lens composition including a base resin including a cardo-based resin having a cardo-based moiety structure and having a refractive index of about 1.5 or more, an acid anhydride-based compound, a silane-based coupling compound, an acidic compound, and an oxime-based photoinitiator.

In one or more embodiments, a refractive index of the lens layer may be in a range of about 1.5 to about 1.7.

In one or more embodiments, the base resin may further include at least one of an acrylate-based monomer, an epoxy-based monomer, or an organic-inorganic composite material.

In one or more embodiments, the lens composition may further include at least one of a urethane-based additive, an antioxidant, an amine-based co-initiator, or a thermal initiator.

In one or more embodiments, the lens composition may further include a solvent, and if (e.g., when) a total amount of the lens composition excluding (e.g., not including) the solvent is 100 wt %, the lens composition may include about 20 wt % to about 50 wt % of the cardo-based resin, about 10 wt % to about 50 wt % of the acid anhydride-based compound, about 1 wt % to about 10 wt % of the silane-based coupling compound, about 10 wt % to about 30 wt % of the acidic compound, and about 0.5 wt % to about 10 wt % of the oxime-based photoinitiator.

In one or more embodiments, the lens composition may further include about 10 wt % to about 30 wt % of a urethane-based additive.

In one or more embodiments, the lens composition may further include about 0.1 wt % to about 3 wt % of an antioxidant.

In one or more embodiments, the lens composition may further include about 0.5 wt % to about 10 wt % of an amine-based co-initiator.

In one or more embodiments, the lens composition may further include about 0.001 wt % to about 5 wt % of a thermal initiator.

In one or more embodiments, a distance between a first lens part and a second lens part adjacent to each other among the plurality of lens parts spaced and/or apart (e.g., spaced apart or separated) from each other and respectively corresponding to the plurality of light-emitting elements may be in a range of about 1.5 μm to about 2.5 μm.

In one or more embodiments, the lens layer may further include an insulating (e.g., electrically insulating) layer disposed or provided on the plurality of lens parts and covering the plurality of lens parts, and the insulating layer may have a refractive index less than a refractive index of the plurality of lens parts.

In one or more embodiments, the lens layer may further include an insulating (e.g., electrically insulating) layer between the plurality of lens parts spaced and/or apart (e.g., spaced apart or separated) from each other, and the insulating layer may have a refractive index less than a refractive index of the lens layer.

According to one or more embodiments, a lens composition for use in a display panel includes a light-emitting element, wherein the lens composition includes a solvent, and if (e.g., when) a total amount of the lens composition excluding (e.g., not including) the solvent is 100 wt %, the lens composition further includes about 20 wt % to about 50 wt % of a base resin including a cardo-based moiety having a refractive index of about 1.5 or more, about 10 wt % to about 50 wt % of an acid anhydride-based compound, about 1 wt % to about 10 wt % of a silane-based coupling compound, about 10 wt % to about 30 wt % of an acidic compound, and about 0.5 wt % to about 10 wt % of an oxime-based photoinitiator.

In one or more embodiments, a refractive index of the lens composition may be in a range of about 1.5 to about 1.7.

In one or more embodiments, the lens composition may further include at least one of a urethane-based compound, an antioxidant, an amine-based co-initiator, or a thermal initiator.

In one or more embodiments, the urethane-based compound may be in a range of about 10 wt % to about 30 wt %, the antioxidant may be in a range of about 0.1 wt % to about 3 wt %, the amine-based co-initiator may be in a range of about 0.5 wt % to about 10 wt %, and the thermal initiator may be in a range of about 0.001 wt % to about 5 wt %.

In one or more embodiments, the base resin may further include at least one of an acrylate-based monomer, an epoxy-based monomer, or an organic-inorganic composite material.

In one or more embodiments, the acrylate-based monomer may be in a range of about 1 wt % to about 35 wt %, and the epoxy-based monomer may be in a range of about 5 wt % to about 15 wt %.

According to one or more embodiments, an electronic device includes a processor and a display panel configured or provided to be controlled by the processor, wherein the display panel includes a light-emitting element on a glass substrate, an encapsulation layer disposed or provided on the light-emitting element and sealing the light-emitting element, and a lens layer disposed or provided on the encapsulation layer and including a lens part disposed or provided to correspond to the light-emitting element, wherein the lens layer includes a lens composition, the lens composition including a base resin including a cardo-based resin having a cardo-based moiety structure and having a refractive index of about 1.5 or more, an acid anhydride-based compound, a silane-based coupling compound, an acidic compound, an oxime-based photoinitiator, and a crosslinking agent.

In one or more embodiments, a refractive index of the lens composition may be in a range of about 1.5 to about 1.7.

Other aspects, effects, and/or embodiments of the present disclosure will become better understood through the accompanying drawings, the appended claims and equivalents thereof, and the detailed description.

These general and specific aspects of embodiments of the present disclosure may be practiced by utilizing systems, methods, computer programs, or any combination thereof.

### BRIEF DESCRIPTION OF THE DRAWINGS

The above and other aspects and features of certain embodiments of the present disclosure will be more apparent and more readily appreciated from the following description of one or more embodiments, taken in conjunction with the accompanying drawings, in which:

FIG. 1 is a block diagram of an electronic device according to one or more embodiments;

FIGS. 2-4 are schematic diagrams of electronic devices according to one or more embodiments;

FIG. 5 is a schematic plan view illustrating a portion of an electronic device according to one or more embodiments;

FIG. 6 is an equivalent circuit diagram schematically illustrating a light-emitting diode of a display panel and a circuit connected to the light-emitting diode, according to one or more embodiments;

FIG. 7 is a cross-sectional view schematically illustrating a display panel according to one or more embodiments;

FIG. 8 is a cross-sectional view schematically illustrating a portion of a display panel according to one or more embodiments;

FIGS. 9-11 are cross-sectional views schematically illustrating a portion of a display panel according to one or more embodiments;

FIG. 12 is a perspective view schematically illustrating an electronic device according to one or more embodiments; and

FIG. 13 is an exploded view schematically illustrating an electronic device according to one or more embodiments.

### DETAILED DESCRIPTION

Reference will be made in more detail to one or more embodiments, examples of which are illustrated in the accompanying drawings, wherein like reference numerals refer to like elements throughout the attached drawings and the written description, and duplicative descriptions thereof may not be provided in the specification. In this regard, the subject matter of the present disclosure may be embodied in different forms and should not be construed as being limited to one or more embodiments set forth herein. Rather, these embodiments are provided as examples, by referring to the drawings, to explain the aspects and features of the present disclosure to those skilled in the art.

The utilization of “may” if (e.g., when) describing embodiments of the present disclosure refers to “one or more embodiments of the present disclosure.”

In the context of the present application and unless otherwise defined, the terms “use,” “using,” and “used” may be considered synonymous with the terms “utilize,” “utilizing,” and “utilized,” respectively.

As used herein, the singular forms “a,” “an,” and “the” are intended to include the plural forms as well, unless the context clearly indicates otherwise. The singular expression includes the plural expression unless the context clearly dictates otherwise.

As used herein, the term “and/or” includes any and all combinations of one or more of the associated listed items. Throughout the present disclosure, the expression “at least one of a, b, or c” indicates only a, only b, only c, both (e.g., simultaneously) a and b, both (e.g., simultaneously) a and c, both (e.g., simultaneously) b and c, all of a, b, and c, or variations thereof.

Throughout the present disclosure, the expressions, such as “at least one of,” “one of,” and “selected from,” if (e.g., when) preceding a list of elements, modify the entire list of elements and do not modify the individual elements of the list. For example, “at least one of a, b, or c,” “at least one selected from among a, b, and c,” “at least one selected from among a to c,” and/or the like indicates only a, only b, only c, both (e.g., simultaneously) a and b, both (e.g., simultaneously) a and c, both (e.g., simultaneously) b and c, all of a, b, and c, or variations thereof.

As the present disclosure allows for one or more suitable changes and embodiments, certain embodiments will be illustrated in the accompanying drawings and described in more detail in the written description. The accompanying drawings to illustrate one or more embodiments are referred to gain or provide a sufficient and better understanding of embodiments, the aspects and features of the present disclosure, and the objectives accomplished by the implementation of the present disclosure. However, the disclosure is not limited to the disclosed embodiments, but may be implemented in one or more suitable different forms.

In the present disclosure, the terms “first,” “second,” and/or the like are not used in a restrictive sense and are used to distinguish one element from another.

In the present disclosure, it will be further understood that the terms “has,” “comprises,” “having,” and/or “comprising” used herein specify the presence of stated features or components, but do not preclude the presence or addition of one or more other features or components. For example, it should be understood that the term “comprise(s)/comprising,” “include(s)/including,” or “have/has/having” specifies the presence of stated features, integers, steps, operations, elements, and/or components, but do not preclude the presence or addition of one or more other features, integers, steps, operations, elements, components, and/or groups thereof. Also, the terms “comprise(s)/comprising,” “include(s)/including,” “have/has/having,” or similar terms include or support the terms “consisting of” and “consisting essentially of,” indicating the presence of stated features, integers, steps, operations, elements, and/or components, without or essentially without the presence of other features, integers, steps, operations, elements, components, and/or groups thereof.

As utilized herein, the terms “substantially,” “about,” or similar terms are used as terms of approximation and not as terms of degree and are intended to account for the inherent deviations in measured or calculated values that would be recognized by those of ordinary skill in the art. “About” as used herein is inclusive of the stated value and refers to as being within an acceptable range of deviation for the particular value as determined by one of ordinary skill in the art, considering the measurement in question and the error associated with measurement of the particular quantity (e.g., the limitations of the measurement system). For example, “about” may refer to as being within one or more standard deviations or within ±30%, ±20%, ±10%, or ±5% of the stated value. Also, it should be understood that, even if (e.g., when) the terms “about,” “approximately,” or “substantially” are not expressly recited in a given element (e.g., a claim element), the scope of such element is intended to include variations that are insubstantial or within the understanding of one of ordinary skill in the art. For example, numerical values and ranges provided herein are intended to include tolerances and measurement uncertainties that would be recognized by those skilled in the art, and the elements (e.g., claim elements) should be construed accordingly to encompass such equivalents.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, for example, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in the present disclosure is intended to include all higher numerical limitations subsumed therein. Accordingly, Applicant reserves the right to amend the disclosure, including the claims, to expressly recite any sub-range subsumed within the ranges expressly recited herein.

It will be further understood that, if (e.g., when) a layer, a region, or an element is referred to as being “on” another layer, region, or element, it may be directly or indirectly on the other layer, region, or element. For example, intervening layers, regions, or elements may be present therebetween. In contrast, if (e.g., when) a layer, a region, or an element is referred to as being “directly on” another layer, region, or element, there are no intervening layers, regions, or elements present therebetween.

Also, sizes of elements in the drawings may be exaggerated or reduced for convenience of explanation. For example, because sizes and thicknesses of elements in the drawings may be arbitrarily illustrated for convenience of explanation, embodiments of the present disclosure are not necessarily limited thereto.

The x-axis, the y-axis, and the z-axis are not limited to three axes of the rectangular coordinate system and may be interpreted in a broader sense. For example, the x-axis, the y-axis, and the z-axis may be normal (e.g., substantially perpendicular) to one another or may represent different directions that are not normal (e.g., substantially perpendicular) to one another.

In the present disclosure, the expression “x direction” may refer to the +x direction and the −x direction, e.g., the ±x direction. In the present disclosure, the expression “y direction” may refer to the +y direction and the −y direction, e.g., the ±y direction. In the present disclosure, the expression “z direction” may refer to the +z direction and the −z direction, e.g., the ±z direction.

The display devices according to one or more embodiments may be applied to one or more suitable electronic devices. An electronic device according to one or more embodiments may include a display device and may further include modules or devices having other additional functions. A display device according to one or more embodiments may include a display panel.

If (e.g., when) a certain embodiment is implemented differently, a specific process sequence may be performed differently from a sequence described herein. For example, two consecutively described processes may be performed substantially at the same time or performed in an order opposite to the stated order.

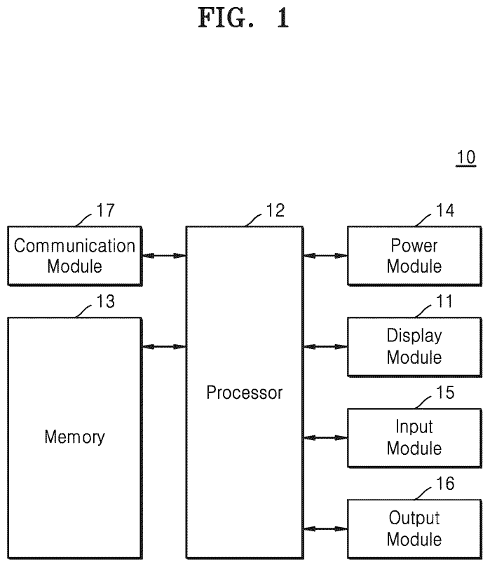

FIG. 1 is a block diagram of an electronic device 10 according to one or more embodiments.

Referring to FIG. 1, the electronic device 10 may include a display panel 11 (e.g., a display module), a processor 12, a memory 13, and a power module 14.

The processor 12 may include at least one of a central processing unit (CPU), an application processor (AP), a graphics processing unit (GPU), a communication processor (CP), an image signal processor (ISP), or a controller. In one or more embodiments, the processor 12 may be functionally or structurally divided into two or more parts. For example, the processor 12 may include a main processor in the form of a first driving chip including a CPU and an auxiliary processor in the form of a second driving chip including a controller configured or provided to receive an image signal from the main processor and process the image signal to conform to the interface specifications of the display panel 11.

The memory 13 may include at least one of volatile memory or non-volatile memory. Data information necessary or desired for the operation of the processor 12 or the display panel 11 may be stored in the memory 13. If (e.g., when) the processor 12 executes an application stored in the memory 13, an image data signal and/or an input control signal may be transmitted to the display panel 11, and the display panel 11 may process the received signal and output image information on a display screen.

The power module 14 may include a power supply module, such as a power adapter or a battery device, and a power conversion module configured or provided to convert power supplied by the power supply module to generate power necessary or desired for the operation of the electronic device 10. The power conversion by the power conversion module may include direct current (DC)-DC conversion, alternating current (AC)-DC conversion, and DC-AC conversion, but embodiments of the present disclosure are not limited thereto.

The electronic device 10 may further include an input module 15, a non-image output module 16, and/or a communication module 17.

The input module 15 may be configured or provided to provide input information to the processor 12 and/or the display panel 11. The input module 15 may include a physical button, a keyboard, a microphone, and other sensor modules. Examples of the sensor modules may include a touch sensor, a pressure sensor, a distance sensor, a position sensor, a digitizer, a motion recognition sensor, a camera sensor, a light-receiving sensor, a photoelectric conversion sensor, a temperature sensor, and a biometric sensor, such as a blood pressure sensor, a blood sugar sensor, an electrocardiogram sensor, or a heart rate sensor.

The non-image output module 16 may be configured or provided to receive non-image information other than the image transmitted from the processor 12 and provide the non-image information to a user. Examples of the non-image output module 16 may include an acoustic module, a haptic module, a light-emitting module, and/or the like and may include other functional modules unique to the electronic device (e.g., a cooling module of a refrigerator and/or the like).

The communication module 17 may be a module responsible for transmitting and receiving information between the electronic device 10 and an external device and may include a receiver and a transmitter. The communication module 17 may include one or more suitable wireless communication modules, such as a mobile communication module, a Wi-Fi™ module, or a Bluetooth module, and one or more suitable wired communication modules.

At least one selected from among the components of the electronic device 10 as described in one or more embodiments may be in the display device. Furthermore, one or more of the individual modules functionally included in a single module may be in the display device, and others may be provided separately from the display device. For example, the display device may include the display panel 11, and the processor 12, the memory 13, and the power module 14 may be provided in the form of other devices within the electronic device 10 other than the display device. As another example, the power module 14 may be provided within the display device and configured or provided to supply power to the processor 12 and the memory 13 provided within the electronic device 10 other than the display device, but embodiments of the present disclosure are not limited to the foregoing examples.

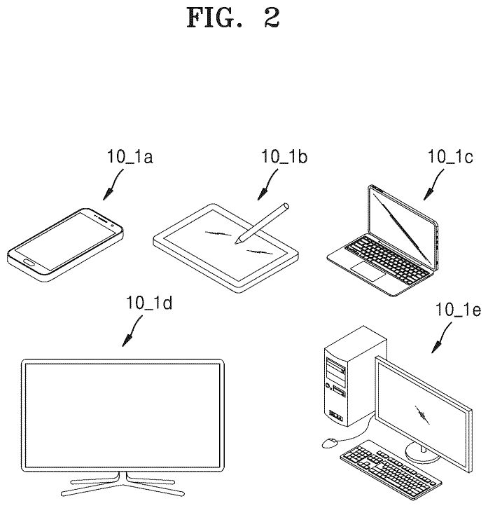

FIGS. 2 to 4 are schematic diagrams of electronic devices according to one or more embodiments. FIGS. 2 to 4 illustrate examples of one or more suitable electronic devices to which the display panel according to one or more embodiments is applied.

FIG. 2 illustrates examples of the electronic device, including a smartphone 10_1a, a tablet personal computer (PC) 10_1b, a laptop 10_1c, a television (TV) 10_1d, and a desk monitor 10_1e.

The smartphone 10_1a may include, in addition to a display panel, a communication module and an input module, such as a touch sensor. The smartphone 10_1a may be configured or provided to process information received through the communication module or another input module and display the information on the display panel of the display device.

Similar to the smartphone 10_1a, each of the tablet PC 10_1b, the laptop 10_1c, the TV 10_1d, and the desk monitor 10_1e may include a display panel and an input module and, in one or more cases, may further include a communication module.

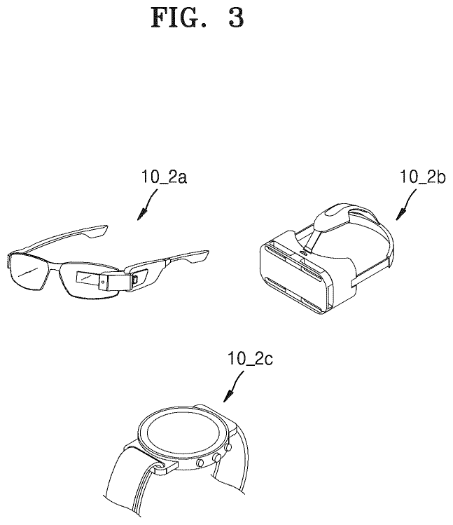

FIG. 3 illustrates examples in which an electronic device including a display panel is applied to a wearable electronic device. The wearable electronic device may be smart glasses 10_2a, a head mounted display 10_2b, a smart watch 10_2c, and/or the like.

Each of the smart glasses 10_2a and the head mounted display 10_2b may include a display panel configured or provided to display a display image and a reflector configured or provided to provide the display image to the user's eyes by reflecting the displayed display image and may provide a virtual reality or augmented reality screen to the user through the display module and the reflector.

The smart watch 10_2c may include a biometric sensor as an input device and may be configured or provided to provide biometric information recognized by the biometric sensor to the user through the display panel.

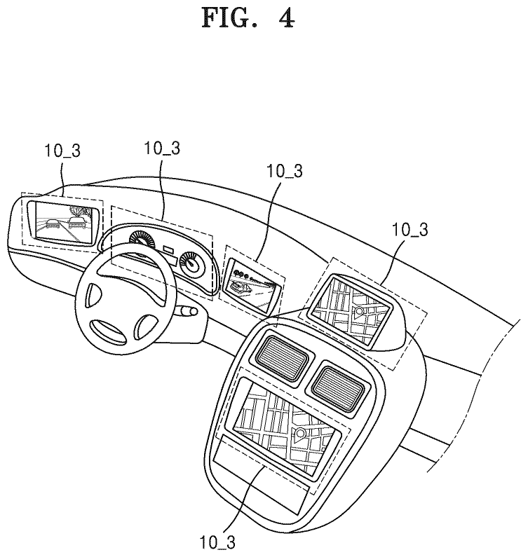

FIG. 4 illustrates an example in which an electronic device including a display panel is applied to a vehicle. For example, an electronic device 10_3 may be applied to dashboards, center fascia, and/or the like of automobiles or may be applied to center information displays (CIDs) on dashboards of automobiles or room mirror displays replacing side mirrors.

In one or more embodiments, the electronic device to which the display panel according to one or more embodiments is applied may include screen display-oriented devices, such as billboards, electronic boards, or game consoles, and one or more suitable home appliances that display information on display panels, such as refrigerators, washing machines, dryers, air conditioners, or robot vacuum cleaners. In one or more embodiments, if (e.g., when) the display panel has a function of transmitting light, the display panel may be applied to electronic devices, such as a smart window or a transparent (e.g., substantially transparent) display device that displays a background and a display image together. The types or kinds of electronic devices according to one or more embodiments are not limited to those described in one or more embodiments, and application of one or more suitable other electronic devices that are not described herein may also be feasible.

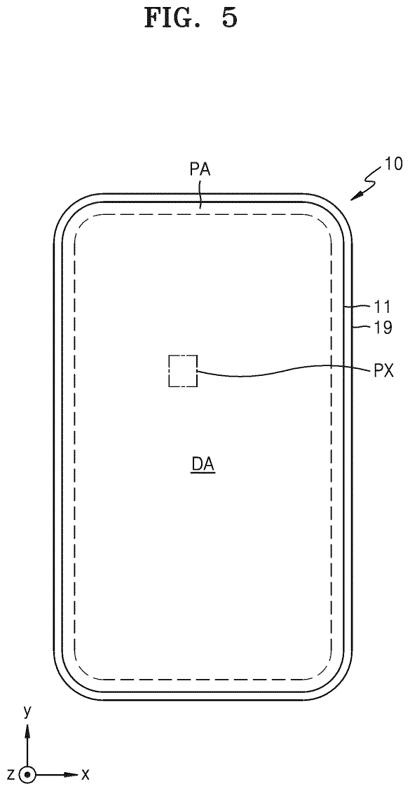

FIG. 5 is a schematic plan view illustrating a portion of an electronic device 10 according to one or more embodiments.

The electronic device 10 may include a display panel 11 and a housing 19. In one or more embodiments, the display panel 11 may be accommodated in the housing 19. The housing 19 may not be necessarily implemented in the form illustrated in FIG. 5, and any suitable housing may belong to the housing 19 of one or more embodiments of the present disclosure without limitations in types or kinds or shapes as long as the housing provides a space in which the display panel 11 may be accommodated. For example, the housing 19 may not need to be completely (e.g., substantially completely) around (e.g., surround) the display panel 11 and may partially cover the display panel 11.

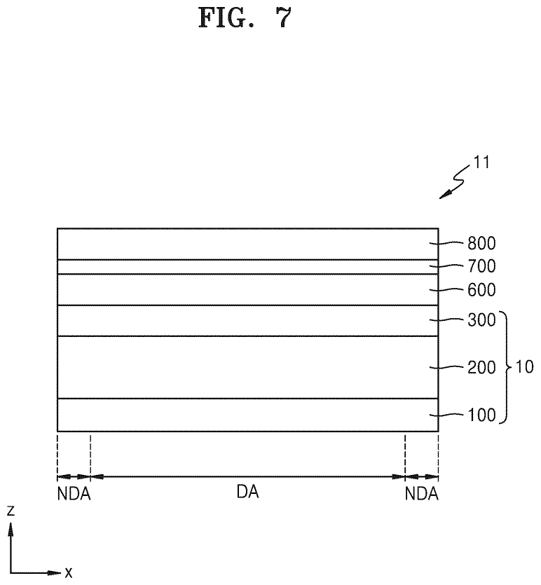

Referring to FIG. 5, the display panel 11 may include a display area DA and a peripheral area PA outside the display area DA. For example, the display panel 11 may define the display area DA and the peripheral area PA outside the display area DA. For example, the display panel 11 may include a substrate (see 100 of FIG. 7), and the display area DA and the peripheral area PA may be defined on the substrate 100.

Pixels may be in the display area DA. The pixels may each include at least one light-emitting diode and a pixel circuit connected to the light-emitting diode to drive the light-emitting diode. The light-emitting diode driven by the pixel circuit may emit light of a specific color (e.g., a specific wavelength band). The display panel 11 may be configured or provided to provide images and/or videos through pieces of light emitted from a plurality of light-emitting diodes respectively provided in a plurality of pixels. In one or more embodiments, the pixels may each include a plurality of grouped sub-pixels. In one or more embodiments, one sub-pixel may include a corresponding light-emitting diode and a corresponding sub-pixel circuit. In one or more embodiments, the light-emitting diodes respectively provided in the plurality of sub-pixels grouped into one pixel may be configured or provided to emit pieces of light of different colors (e.g., different wavelength bands). The peripheral area PA may be a non-display area, and signal lines and/or voltage lines configured or provided to drive the light-emitting diodes may be in the peripheral area PA.

Although FIG. 5 illustrates that each of the display panel 11 and the display area DA has a substantially rectangular shape with round corners, embodiments of the present disclosure are not necessarily limited thereto. The display panel 11 and/or the display area DA may have other shapes, for example, a polygonal shape (e.g., a substantially polygonal shape), a circular shape (e.g., a substantially circular shape), an elliptical shape (e.g., a substantially elliptical shape), or an irregular shape.

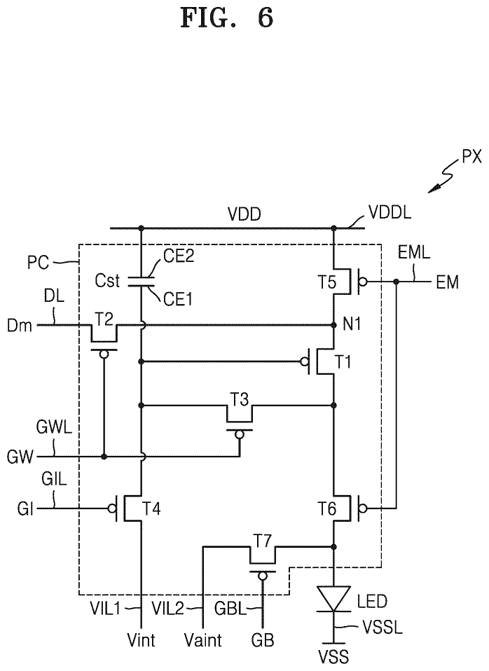

FIG. 6 is an equivalent circuit diagram schematically illustrating a light-emitting diode of a display panel and a circuit connected to the light-emitting diode, according to one or more embodiments.

The display panel 11 as described with reference to FIG. 5 may be configured or provided to provide an image through pixels PX disposed or provided two-dimensionally in the display area DA. Each of the pixels PX may include a light-emitting diode LED. The expression that “the display panel 11 of FIG. 5 includes the pixels PX disposed or provided two-dimensionally in the display area DA” may refer to that the display panel 11 includes light-emitting diodes LED disposed or provided two-dimensionally in the display area DA. The light-emitting diode LED may be electrically connected to a pixel circuit PC. Like the light-emitting diode LED, the pixel circuit PC may be in the display area DA.

The pixel circuit PC may include a first transistor T1, a second transistor T2, a third transistor T3, a fourth transistor T4, a fifth transistor T5, a sixth transistor T6, a seventh transistor T7, and a storage capacitor Cst. The first transistor T1 may be a driving transistor, and the second transistor T2, the third transistor T3, the fourth transistor T4, the fifth transistor T5, the sixth transistor T6, and the seventh transistor T7 may each be a switching transistor.

The first to seventh transistors T1, T2, T3, T4, T5, T6, and T7 may each be a p-channel metal-oxide semiconductor field effect transistor (MOSFET) (PMOS) or an n-channel MOSFET (NMOS). In one or more embodiments, FIG. 6 illustrates that the first to seventh transistors T1, T2, T3, T4, T5, T6, and T7 are each a PMOS. The first to seventh transistors T1, T2, T3, T4, T5, T6, and T7 may each be a transistor having a low-temperature polycrystalline silicon (LTPS) semiconductor layer.

Although FIG. 6 illustrates that the first to seventh transistors T1, T2, T3, T4, T5, T6, and T7 are each a PMOS, embodiments of the present disclosure are not limited thereto. In one or more embodiments, the first to seventh transistors T1, T2, T3, T4, T5, T6, and T7 may each be an NMOS. In one or more embodiments, at least one selected from among the first to seventh transistors T1, T2, T3, T4, T5, T6, and T7 may be a PMOS or an NMOS. For example, the third transistor T3 and the fourth transistor T4 among the first to seventh transistors T1, T2, T3, T4, T5, T6, and T7 may each be an NMOS, and the others may each be a PMOS. For example, the fifth transistor T5 among the first to seventh transistors T1, T2, T3, T4, T5, T6, and T7 may be a PMOS, and the others may each be an NMOS.

A case where the first to seventh transistors T1, T2, T3, T4, T5, T6, and T7 are each a transistor having an LTPS semiconductor layer has been described with reference to FIG. 6, but embodiments of the present disclosure are not limited thereto. In one or more embodiments, the first to seventh transistors T1, T2, T3, T4, T5, T6, and T7 may each be a transistor having an oxide semiconductor layer. In one or more embodiments, at least one selected from among the first to seventh transistors T1, T2, T3, T4, T5, T6, and T7 may be a transistor having an LTPS semiconductor layer, and the others may each be a transistor having an oxide semiconductor layer. In one or more embodiments, the third transistor T3 and the fourth transistor T4 may each include an oxide semiconductor layer having low leakage current, and the first, second, fifth, sixth, and seventh transistors T1, T2, T5, T6, and T7 may each include a semiconductor layer including polycrystalline silicon. In one or more embodiments, the fifth transistor T5 may include a semiconductor layer including polycrystalline silicon, and the first, second, third, fourth, sixth, and seventh transistors T1, T2, T3, T4, T6, and T7 may each include an oxide semiconductor layer.

The pixel circuit PC may be electrically connected to signal lines and voltage lines. The signal lines may include a data line DL and gate lines, such as a scan signal line GWL, a bypass control line GBL, an initialization control line GIL, and an emission control line EML. The voltage lines may include first and second initialization voltage lines VIL1 and VIL2 and a first voltage line VDDL.

The first voltage line VDDL may be configured or provided to transmit a first power supply voltage VDD to the first transistor T1. The first initialization voltage line VIL1 may be configured or provided to transmit, to the pixel circuit PC, a first initialization voltage Vint to initialize the first transistor T1. The second initialization voltage line VIL2 may be configured or provided to transmit, to the pixel circuit PC, a second initialization voltage Vaint to initialize a first electrode of a light-emitting diode LED.

The first transistor T1 may be electrically connected to the first voltage line VDDL via the fifth transistor T5 and may be electrically connected to the light-emitting diode LED via the sixth transistor T6. The first transistor T1, which acts as a driving transistor, may be configured or provided to receive a data signal Dm according to the switching operation of the second transistor T2 and supply a driving current to the light-emitting diode LED.

The second transistor T2, which acts as a data write transistor, may be electrically connected to the scan signal line GWL and the data line DL. The second transistor T2 may be electrically connected to the first voltage line VDDL via the fifth transistor T5. The second transistor T2 may be configured or provided to be turned on in response to a scan signal GW received through the scan signal line GWL and perform a switching operation to transmit the data signal Dm received through the data line DL to a first node N1.

The third transistor T3 may be electrically connected to the scan signal line GWL and electrically connected to the light-emitting diode LED via the sixth transistor T6. The third transistor T3 may be configured or provided to be turned on in response to the scan signal GW received through the scan signal line GWL and diode-connect the first transistor T1.

The fourth transistor T4, which acts as a first initialization transistor, may be electrically connected to the initialization control line GIL and the first initialization voltage line VIL1. The fourth transistor T4 may be configured or provided to be turned on in response to an initialization control signal GI received through the initialization control line GIL and initialize a voltage of a gate electrode of the first transistor T1 by transmitting the first initialization voltage Vint from the first initialization voltage line VIL1 to the gate electrode of the first transistor T1. The initialization control signal GI may correspond to a scan signal of another pixel circuit in a previous row of the corresponding pixel circuit PC.

The fifth transistor T5 may act as an operation control transistor, and the sixth transistor T6 may act as an emission control transistor. The fifth transistor T5 and the sixth transistor T6 may be electrically connected to the emission control line EML and may be configured or provided to be concurrently (e.g., simultaneously) turned on in response to an emission control signal EM received through the emission control line EML and form a current path through which the driving current flows in a direction from the first voltage line VDDL to the light-emitting diode LED. The first electrode of the light-emitting diode LED may be electrically connected to the first transistor T1 through the sixth transistor T6, and a second electrode of the light-emitting diode LED may be electrically connected to a second voltage line VSSL configured or provided to supply a second power supply voltage VSS.

The seventh transistor T7, which acts as a second initialization transistor, may be electrically connected to the bypass control line GBL, the second initialization voltage line VIL2, and the sixth transistor T6. The seventh transistor T7 may be configured or provided to be turned on in response to a bypass control signal GB received through the bypass control line GBL and initialize the first electrode of the light-emitting diode LED by transmitting the second initialization voltage Vaint from the second initialization voltage line VIL2 to the first electrode of the light-emitting diode LED.

The storage capacitor Cst may include a first capacitor electrode CE1 and a second capacitor electrode CE2. The first capacitor electrode CE1 may be electrically connected to the gate electrode of the first transistor T1 and the second capacitor electrode CE2 may be electrically connected to the first voltage line VDDL. The storage capacitor Cst may store and maintain a voltage corresponding to a voltage difference between the first voltage line VDDL and the gate electrode of the first transistor T1, and thus, the voltage applied to the gate electrode of the first transistor T1 may be maintained.

FIG. 6 illustrates that the first and second initialization voltage lines VIL1 and VIL2 are electrically connected to the fourth transistor T4 and the seventh transistor T7, respectively, but embodiments of the present disclosure are not limited thereto. In one or more embodiments, the first and second initialization voltage lines VIL1 and VIL2 may be substantially the same initialization voltage lines, and a single initialization voltage line may be electrically connected to both (e.g., simultaneously) the fourth transistor T4 and the seventh transistor T7.

FIG. 6 illustrates that the pixel circuit PC includes seventh transistors and one capacitor, but embodiments of the present disclosure are not limited thereto. In one or more embodiments, the pixel circuit PC may include three, four, five, six, or eighth or more transistors and two or more capacitors.

FIG. 7 is a cross-sectional view schematically illustrating a display panel according to one or more embodiments.

Referring to FIG. 7, a display panel 11 and a plurality of layers above the display panel 11 may be included. In one or more embodiments, the display panel 11 may include a substrate 100, a display layer 200, an encapsulation layer 300, a touch sensor layer, a functional layer 600, a lens layer 700, and a cover window 800.

The substrate 100 may include glass. For example, the substrate 100 may include a thin-film glass substrate, for example, soda lime glass containing alkali metal oxide or alkali-free glass. In one or more embodiments, the substrate 100 may include a polymer resin. For example, the polymer resin may include polyethersulfone, polyacrylate, polyether imide, polyethylene naphthalate, polyethylene terephthalate, polyphenylene sulfide, polyarylate, polyimide, polycarbonate, and/or cellulose acetate propionate. The substrate 100 including the polymer resin may be flexible, rollable, or bendable. The substrate 100 may have a multilayer structure including a polymer resin-containing layer and an inorganic layer.

The display layer 200 may include thin-film transistors electrically connected to light-emitting diodes, for example, organic light-emitting diodes, and insulating (e.g., electrically insulating) layers therebetween.

The encapsulation layer 300 may be on the display layer 200. For example, the display layer 200 may be sealed by the encapsulation layer 300. The encapsulation layer 300 may include at least one inorganic encapsulation layer and at least one organic encapsulation layer.

In one or more embodiments, instead of the encapsulation layer 300, an encapsulation substrate including a glass material may be provided. The encapsulation substrate may be on the display layer 200, and the display layer 200 may be between the substrate 100 and the encapsulation substrate. A gap may exist between the encapsulation substrate and the display layer 200, and the gap may be filled with a filler.

The functional layer 600 may be on the encapsulation layer 300.

In one or more embodiments, if (e.g., when) the display panel 11 needs or is desired to perform a touch function according to a user input on the outer surface thereof, the touch sensor layer may be disposed or provided on the encapsulation layer 300. The touch sensor layer may be configured or provided to sense an external input, for example, a touch of a finger or an object, such as a stylus pen, so that (e.g., such that) the display panel 11 may obtain coordinate information corresponding to a touch position. The touch sensor layer may include touch electrodes and trace lines connected to the touch electrodes. The touch sensor layer may be configured or provided to sense an external input by using a mutual capacitance method and/or a self-capacitance method. The touch sensor layer may be directly on the encapsulation layer 300. In one or more embodiments, the touch sensor layer may be formed or provided separately and then bonded to the encapsulation layer 300 through an adhesive layer, such as an optically clear (e.g., substantially clear) adhesive.

In one or more embodiments, if (e.g., when) the display panel 11 does not need or is not desired to perform a touch function as described herein, the touch sensor layer may not be provided.

If (e.g., when) the display panel 11 includes a touch sensor layer, the functional layer 600 may be disposed or provided on the touch sensor layer. In one or more embodiments, if (e.g., when) the touch sensor layer is not provided in the display panel 11, the functional layer 600 may be disposed or provided directly on the encapsulation layer 300. The functional layer 600 may improve or enhance the color reproducibility by improving or enhancing the transmittance of light emitted from the display layer 200. Furthermore, the functional layer 600 may reduce the reflectivity of light incident from the outside toward the display panel 11, e.g., external light.

In one or more embodiments, the functional layer 600 may include a light blocking layer and color filters. The color filters may be disposed or provided by taking into account the color of light emitted from each of the light-emitting diodes of the display layer 200. In one or more embodiments, the functional layer 600 may include a polarizing film. In this case, the functional layer 600 may include a retarder and/or a polarizer. The retarder may be a film-type or kind retarder or a liquid crystal coating-type or kind retarder and may include a λ/2 retarder and/or a λ/4 retarder. The polarizer may be a film-type or kind polarizer or a liquid crystal coating-type or kind polarizer. The film-type or kind retarder or polarizer may include a stretched synthetic resin film, and the liquid crystal coating-type or kind retarder or polarizer may include liquid crystals disposed or provided in a certain (e.g., set or predetermined) array. Each of the retarder and the polarizer may further include a protection film.

For convenience of explanation, a case where the functional layer 600 includes the light blocking layer and the color filters is mainly or predominantly described.

The lens layer 700 may be on the functional layer 600. The lens layer 700 may prevent glare (or reduce a degree or occurrence of glare) by reducing light reflection. In one or more embodiments, the lens layer 700 may include a lens composition including a resin and may be formed or provided by patterning the lens composition. In one or more embodiments, the lens layer 700 may be formed or provided on the functional layer 600 through direct patterning. At this time, the terms “direct patterning” may be a process to form or provide a lens composition on the functional layer 600 and then form or provide a lens shape by patterning and etching the lens composition through direct exposure and development without utilizing a photoresist (PR).

The lens layer 700 may be provided as a high refractive layer. In one or more embodiments, the refractive index of the lens layer 700 may be in a range of about 1.5 to about 1.8, and, for example, in a range of about 1.5 to about 1.7. The lens layer 700 having a high refractive index may be implemented by including a resin having a high refractive index of about 1.5 or more, and, for example, about 1.6 or more, in the lens composition.

The cover window 800 may be on the lens layer 700. The cover window 800 may protect the layers covering the display panel 11 and/or the like. The cover window 800 may be formed or provided separately and then attached to the lens layer 700 by an adhesive layer between the cover window 800 and the lens layer 700. The adhesive layer may be, for example, an optically clear (e.g., substantially clear) adhesive. In one or more embodiments, the cover window 800 may be directly formed or provided on the lens layer 700. In one or more embodiments, the cover window 800 may not be provided.

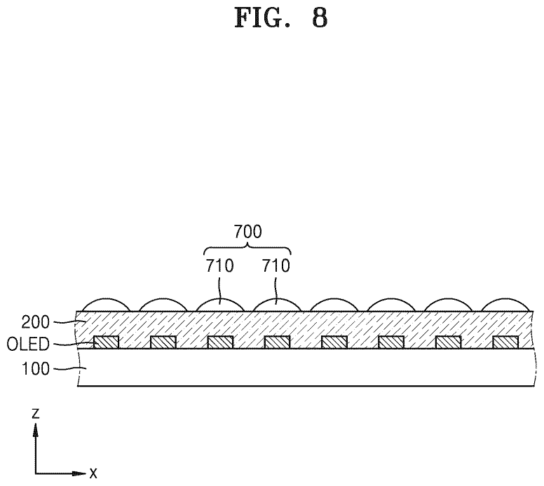

FIG. 8 is a cross-sectional view schematically illustrating a portion of the display panel 11 according to one or more embodiments.

Referring to FIG. 8, the display panel 11 may include a substrate 100, a display layer 200 disposed or provided on the substrate 100 and including light-emitting elements, for example, organic light-emitting diodes OLED, and a lens layer 700 on the display layer 200. For convenience of explanation, an example in which the lens layer 700 is disposed or provided on the display layer 200 is illustrated in FIG. 8, but as described with reference to FIG. 7, one or more suitable layers may be between the display layer 200 and the lens layer 700.

The lens layer 700 may include a plurality of lens parts 710. The lens parts 710 may be respectively disposed or provided above the organic light-emitting diodes OLED and may be spaced and/or apart (e.g., spaced apart or separated) from each other.

The lens part 710 may include a lens composition. The lens composition may include a base resin including a cardo-based resin having a cardo-based moiety structure and having a refractive index of about 1.5 or more, an acid anhydride-based compound, a silane-based coupling compound, an acrylic-based acidic compound including an acrylic group, an oxime-based photoinitiator, and a solvent.

The base resin may act as a support within the lens composition. The base resin may include a cardo-based resin having a cardo-based moiety structure. The base resin may include the cardo-based resin, allowing the lens composition to have a high refractive index of about 1.5 or more and enabling fine patterning and control of reflow in the process of patterning the lens part 710 by utilizing the lens composition.

The cardo-based resin may include, for example, a compound represented by Formula 1. Because the cardo-based resin has a fluorene-type or kind structure as shown in Formula 1, the cardo-based resin may have excellent or suitable heat resistance and dimensional stability and may have excellent or suitable adhesion to a lower layer.

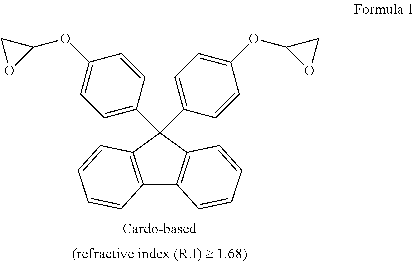 [SMILES: c1ccc2c(c1)-c1ccccc1C2(c1ccc(OC2CO2)cc1)c1ccc(OC2CO2)cc1]

An average molecular weight of the cardo-based resin may be in a range of about 1,000 g/mol to about 200,000 g/mol. If (e.g., when) the cardo-based resin has an average molecular weight within the foregoing range, the cardo-based resin may have excellent or suitable patterning performance and improved or enhanced adhesion to the lower layer, thus improving or resolving problems such as film lifting.

The cardo-based resin may have a refractive index of about 1.5 or more. For example, the cardo-based resin may have a refractive index of about 1.68 or more, about 1.70 or more, or about 1.71 or more. Because the cardo-based resin has a high refractive index as described herein, the lens composition including the cardo-based resin may have high refractive index characteristics. Therefore, the refractive index of the lens composition including the cardo-based resin may be about 1.5 or more.

If (e.g., when) the sum of all components excluding (e.g., not including) a solvent in the lens composition is 100 wt %, the cardo-based resin may be in an amount of about 20 wt % to about 50 wt %. If (e.g., when) the cardo-based resin is included in the lens composition within the foregoing range, the refractive index of the lens composition may be satisfied and heat resistance and patterning performance may be excellent or suitable.

In one or more embodiments, the base resin may further include, in addition to the cardo-based resin, an epoxy-based monomer. If (e.g., when) the base resin further includes an epoxy-based monomer, a degree of curing of the lens composition may be controlled and a crosslinking point may be increased. Examples of the epoxy-based monomer may include an epoxycyclohexylmethyl epoxycyclohexanecarboxylate-based compound, an epoxycyclohexane carboxylate-based compound of alkanediol, an epoxycyclohexylmethylester-based compound of dicarboxylic acid, an epoxycyclohexylmethylether-based compound of polyethylene glycol, an epoxycyclohexylmethylether-based compound of alkanediol, a diepoxytrispiro-based compound, a diepoxymonospiro-based compound, a vinylcyclohexenediepoxide-based compound, an epoxycyclopentylether-based compound, and/or a diepoxytricyclodecane-based compound. For example, examples of the epoxy-based monomer may include an ester compound of 3,4-epoxycyclohexylmethyl-3′,4′-epoxycyclohexane carboxylate (ECC), 7-oxabicyclo[4,1,0]heptane-3-carboxylic acid, and (7-oxa-bicyclo[4,1,0]hepto-3-yl)methanol; an ester compound of 4-methyl-7-oxabicyclo[4,1,0]heptane-3-carboxylic acid and (4-methyl-7-oxa-bicyclo[4,1,0]hepto-3-yl)methanol; an ester compound of 7-oxabicyclo[4,1,0]heptane-3-carboxylic acid and 1,2-ethanediol; an ester compound of (7-oxabicyclo[4,1,0]hepto-3-yl)methanol and adipic acid; an ester compound of (4-methyl-7-oxabicyclo[4,1,0]hepto-3-yl)methanol and adipic acid; or an ether compound of (7-oxabicyclo[4,1,0]hepto-3-yl)methanol and 1,2-ethanediol. Among the epoxy-based monomers as described herein, the ECC may have a structure represented by Formula 2.

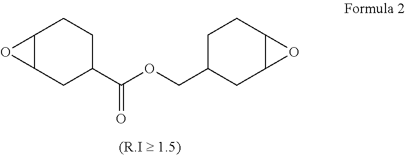 [SMILES: O=C(OCC1CCC2OC2C1)C1CCC2OC2C1]

In one or more embodiments, the base resin may further include, in addition to the cardo-based resin, an acrylate-based monomer. The acrylate-based monomer may include, for example, at least one selected from among the structures represented by Formula 3.

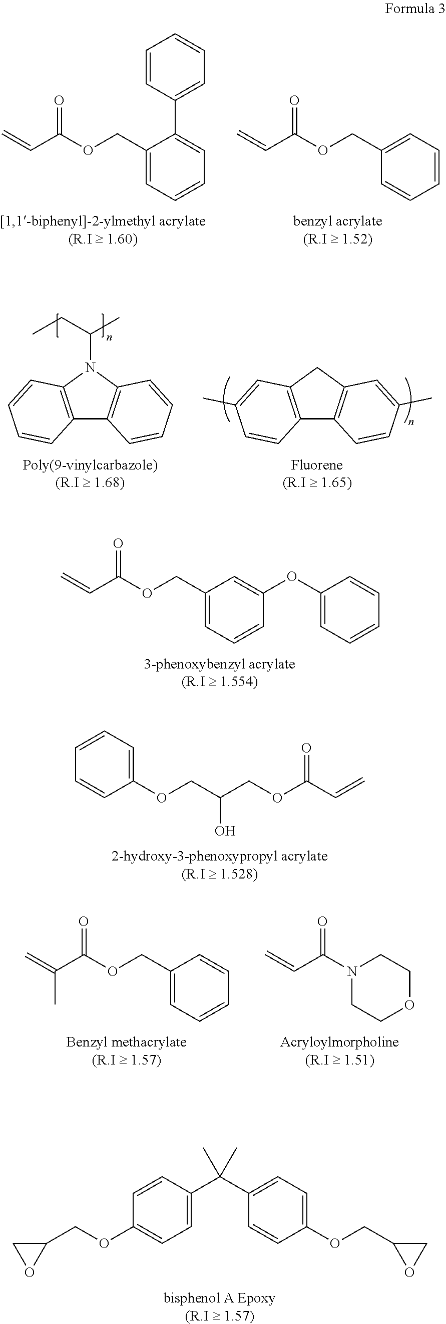

In one or more embodiments, examples of the acrylate-based monomer may include at least one of benzyl(meth)acrylate, methyl(meth)acrylate, ethyl(meth)acrylate, butyl(meth)acrylate, dimethylaminoethyl(meth)acrylate, isobutyl(meth)acrylate, t-butyl(meth)acrylate, cyclohexyl(meth)acrylate, isobornyl(meth)acrylate, ethylhexyl-(meth)acrylate, 2-phenoxyethyl(meth)acrylate, tetrahydrofurfuryl(meth)acrylate, hydroxyethyl(meth)acrylate, 2-hydroxypropyl(meth)acrylate, 2-hydroxy-3-chloropropyl(meth)acrylate, 4-hydroxybutyl (meth)acrylate, acyl octyloxy-2-hydroxypropyl(meth)acrylate, glycerol(meth)acrylate, 2-methoxyethyl(meth)acrylate, 3-methoxybutyl(meth)acrylate, ethoxydiethyleneglycol(meth)acrylate, methoxytriethyleneglycol(meth)acrylate, methoxytripropyleneglycol(meth)acrylate, poly(ethylene glycol)methylether(meth)acrylate, phenoxydiethyleneglycol(meth)acrylate, p-nonylphenoxypolyethyleneglycol(meth)acrylate, p-nonylphenoxypolypropyleneglycol(meth)acrylate, glycidyl(meth)acrylate, tetrafluoropropyl(meth)acrylate, 1,1,1,3,3,3-hexafluoroisopropyl(meth)acrylate, octafluoropentyl(meth)acrylate, heptadecafluorodecyl(meth)acrylate, tribromophenyl(meth)acrylate, dicyclopentanylmethacrylate, dicyclopentenyl methacrylate, dicyclopentenyloxy ethylacrylate, isobornyl methacrylate, adamantyl methacrylate, methyl α-hydroxymethyl acrylate, ethyl α-hydroxymethyl acrylate, propyl α-hydroxymethyl acrylate, or butyl α-hydroxymethyl acrylate.

In one or more embodiments, the base resin may further include an organic-inorganic composite material. As the base resin further includes an organic-inorganic composite material, if (e.g., when) the lower layer is an inorganic layer to which the lens composition is applied, the adhesion to the lower layer may be improved or enhanced. The organic-inorganic composite material may have a structure represented by, for example, Formula 4.

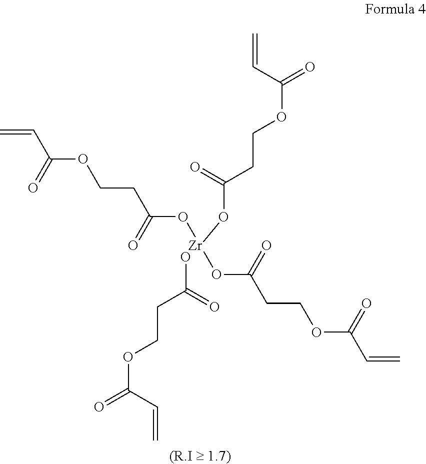

In the compounds as described in one or more embodiments, the epoxy-based monomer and/or the acrylate-based monomer in the base resin may have a refractive index of about 1.5 or more, and, for example, about 1.70 or more or about 1.71 or more. Because the epoxy-based monomer and/or the acrylate-based monomer in the base resin has a high refractive index, the lens composition may have high refractive index characteristics. Therefore, the refractive index of the lens composition including the base resin as described in one or more embodiments may be in a range of about 1.5 to about 1.8, and, for example, about 1.5 to about 1.7.

An average molecular weight of the base resin may be in a range of about 1,000 g/mol to about 200,000 g/mol. If (e.g., when) the average molecular weight of the base resin is less than about 1,000 g/mol, the bonding function between the components may be weak and the physical properties may not be satisfied. For example, patterns may be lost during a development process. If (e.g., when) the average molecular weight of the base resin is greater than about 200,000 g/mol, the efficiency of the process may be reduced during patterning and excessive or substantial reflow may occur, making it difficult to ensure uniformity in the pattern thickness.

In one or more embodiments, the lens composition may include an acid anhydride compound. In the lens composition excluding (e.g., not including) the solvent, the silane-based coupling compound may be in an amount of about 10 wt % to about 50 wt %. In the lens composition, the acid anhydride compound may act as a heat-resistant agent or a curing agent.

The acid anhydride compounds may be a monomer or a polymer. Any acid anhydride compound may be used without limitation as long as the acid anhydride compound is an acid anhydride monomer having a positive birefringence. For example, the acid anhydride compound may be an acid anhydride monomer including an annular structure. For example, the acid anhydride monomer may be, for example, at least one selected from phthalic anhydride and maleic anhydride. In one or more embodiments, a carboxylic anhydride may be used, and a monovalent carboxylic anhydride or a divalent or higher polyvalent carboxylic anhydride may be used. In one or more embodiments, the acid anhydride compound may include at least one selected from among the structures represented by Formula 5. If (e.g., when) the lens composition includes the acid anhydride monomer within the foregoing range, the curability and heat resistance of the entire lens composition may be increased.

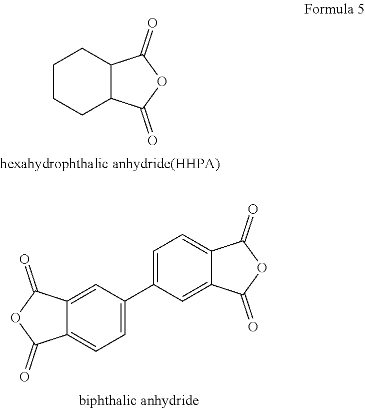 [SMILES: O=C1OC(=O)C2CCCCC12 ; O=C1OC(=O)c2cc(-c3ccc4c(c3)C(=O)OC4=O)ccc21]

In one or more embodiments, the lens composition may include a silane-based coupling compound. In the lens composition excluding (e.g., not including) the solvent, the silane-based coupling compound may be in an amount of about 1 wt % to about 10 wt %.

Examples of the silane-based coupling compound may include at least one selected from among a silicon compound having an epoxy structure, such as 3-glycidoxy propyl trimethoxysilane, 3-glycidoxy propylmethyl dimethoxysilane, or 2-(3,4-epoxycyclohexyl)ethyl trimethoxysilane, a polymerizable unsaturated group-containing silicon compound, such as vinyl trimethoxy silane, vinyl triethoxy silane, or (meth)acryloxy propyl trimethoxysilane, an amino group-containing silicon compound, such as 3-aminopropyl trimethoxysilane, N-(2-aminoethyl)-3-aminopropyl trimethoxysilane, or N-(2-aminoethyl)-3-aminopropyl methyl dimethoxysilane, and 3-chloropropyl trimethoxysilane, but embodiments of the present disclosure are not limited thereto. In one or more embodiments, a silane coupling agent having an epoxy structure may be used. In one or more embodiments, the silane coupling compound may include at least one selected from among the structures represented by Formula 6. If (e.g., when) the lens composition includes the silane coupling compound within the foregoing range, the lens composition may have improved or enhanced film lifting, excellent or suitable adhesion, and excellent or suitable storage stability with the base resin.

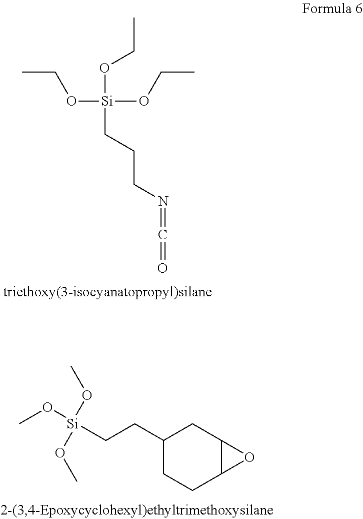

In one or more embodiments, the lens composition may include an acidic compound. In the lens composition excluding (e.g., not including) the solvent, the acidic compound may be in an amount of about 10 wt % to about 30 wt %. The acidic compound may include a hydroxyl group and/or a carboxyl group. For example, the acidic compound may include (meth)acrylic acid, benzoic acid, carboxylic acid, hydroxycarboxylic acid, hydroxylic acid, and/or the like. In one or more embodiments, the acidic compound may include at least one selected from among the structures represented by Formula 7. The acidic compound may improve or enhance the developability by including the material as described herein in the lens composition within the foregoing range.

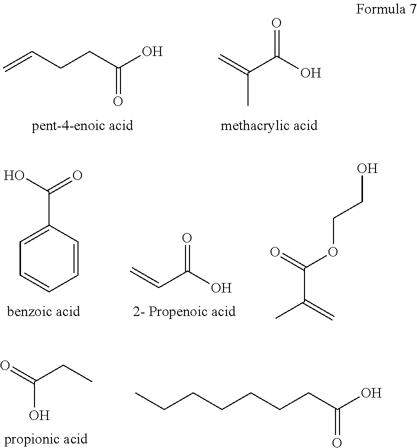

In one or more embodiments, the lens composition may include a photoinitiator. In the lens composition excluding (e.g., not including) the solvent, the photoinitiator may be in an amount of about 0.5 wt % to about 10 wt %. Examples of the photoinitiator may include at least one selected from among a triazine compound, such as 2,4-trichloromethyl-(4′-methoxyphenyl)-6-triazine, 2,4-trichloromethyl-(4′-methoxystyryl)-6-triazine, 2,4-trichloromethyl-(pipronyl)-6-triazine, 2,4-trichloromethyl-(3′,4′-dimethoxyphenyl)-6-triazine, or 3-{4-[2,4-bis(trichloromethyl)-s-triazin-6-yl]phenylthio}propanoic acid, a biimidazole compound, such as 2,2′-bis(2-chlorophenyl)-4,4′,5,5′-tetraphenyl biimidazole or 2,2′-bis(2,3-dichlorophenyl)-4,4′,5,5′-tetraphenyl biimidazole, an acetophenone compound (e.g., Irgacure-369), such as 2-hydroxy-2-methyl-1-phenylpropan-1-one, 1-(4-isopropylphenyl)-2-hydroxy-2-methylpropan-1-one, 4-(2-hydroxyethoxy)-phenyl (2-hydroxy)propyl ketone, 1-hydroxycyclohexylphenyl ketone, 2,2-dimethoxy-2-phenyl acetophenone, 2-methyl-(4-methylthiophenyl)-2-morpholino-1-propan-1-one (Irgacure-907), or 2-benzyl-2-dimethylamino-1-(4-morpholinophenyl)-butan-1-one, a benzophenone compound, such as 4,4′-bis(dimethylamino)benzophenone or 4,4′-bis(diethylamino)benzophenone, a thioxanthone compound, such as 2,4-diethyl thioxanthone, 2-chloro thioxanthone, isopropyl thioxanthone, or diisopropyl thioxanthone, a phosphine oxide compound, such as 2,4,6-trimethylbenzoyl diphenylphosphine oxide, bis(2,6-dimethoxybenzoyl)-2,4,4-trimethylpentyl phosphine oxide, or bis(2,6-dichlorobenzoyl) propyl phosphine oxide, and a coumarin compound, such as 3,3′-carbonylvinyl-7-(diethylamino)coumarin, 3-(2-benzothiazolyl)-7-(diethylamino)coumarin, 3-benzoyl-7-(diethylamino)coumarin, 3-benzoyl-7-methoxy-coumarin, or 10,10′-carbonylbis[1,1,7,7-tetramethyl-2,3,6,7-tetrahydro-1H,5H,11H—Cl]-benzopyrano[6,7,8-ij]-quinolizin-11-one. In one or more embodiments, the photoinitiator may include an oxime-based photoinitiator. For example, the photoinitiator may include an O-acyloxime-based compound, such as Irgacure OXE 01 or Irgacure OXE 02 available from CibaGeigy. The oxime-based photoinitiator may include, for example, at least one selected from among the structures represented by Formula 8.

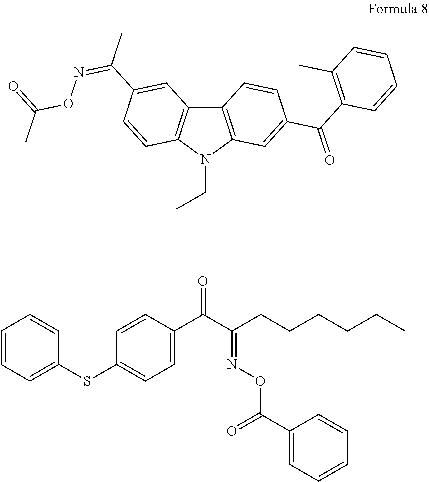 [SMILES: CCn1c2ccc(/C(C)=N\OC(C)=O)cc2c2ccc(C(=O)c3ccccc3C)cc21 ; CCCCCC/C(=N\OC(=O)c1ccccc1)C(=O)c1ccc(Sc2ccccc2)cc1]

In one or more embodiments, the lens composition may further include at least one selected from among a urethane-based additive, an antioxidant, an amine-based co-initiator, a thermal initiator, and a crosslinking agent.

In one or more embodiments, the lens composition may include a urethane-based additive. In the lens composition excluding (e.g., not including) the solvent, the urethane-based additive may be in an amount of about 10 wt % to about 30 wt %. For example, the urethane-based additive may have a structure represented by Formula 9.

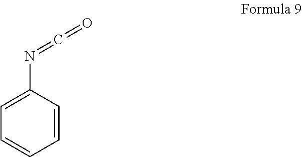

In one or more embodiments, the lens composition may include an antioxidant. In the lens composition excluding (e.g., not including) the solvent, the antioxidant may be in an amount of about 0.1 wt % to about 3 wt %. The antioxidant may be added to prevent spontaneous polymerization (or to reduce a degree or occurrence of spontaneous polymerization) during storage of the lens composition, and may include butylated hydroxytoluene (BHT) and/or Irganox (Ciba AG, Basel, Switzerland).

In one or more embodiments, the lens composition may include an amine-based co-initiator. In the lens composition excluding (e.g., not including) the solvent, the amine-based co-initiator may be in an amount of about 0.5 wt % to about 10 wt %. The amine-based co-initiator may be added to assist the curing of the lens composition. Examples of the amine-based co-initiator may include at least one selected from among trimethylamine, triethylamine, trialkylaminoalkylethanolamine, N,N,N′,N′-tetraalkylhexanediamine, trialkylamine, and imidazole. The “alkyl” is not particularly limited, but may be, for example, an alkyl group having 1 to 20 carbon atoms, 1 to 16 carbon atoms, or 1 to 12 carbon atoms. For example, the amine-based co-initiator may have a structure represented by Formula 10.

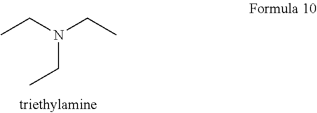

In one or more embodiments, the lens composition may include a thermal initiator for low-temperature curing. In the lens composition excluding (e.g., not including) the solvent, the thermal initiator for low-temperature curing may be in an amount of about 0.001 wt % to about 5 wt %. By adding the thermal initiator for low-temperature curing, the lens composition may be cured at about 85° C. or less, which may prevent a lower layer and/or element, onto which the lens composition is applied, from being damaged due to heat (or reduce a degree to or occurrence of which a lower layer and/or element, onto which the lens composition is applied, is damaged due to heat). In one or more embodiments, the curing reaction of the lens composition may be promoted and the physical properties of the adhesive, such as heat resistance, water resistance, or adhesiveness, may be further improved or enhanced.

Examples of the thermal initiator for low-temperature curing may include a general thermal initiator, such as an imidazole-based thermal initiator, a nitrile-based thermal initiator, a peroxide-based thermal initiator, an azo-based thermal initiator, and/or a redox-based thermal initiator. In one or more embodiments, the imidazole-based thermal initiator may be used as the thermal initiator for low-temperature curing. Examples of the imidazole-based thermal initiator may include 2-methylimidazole, 1-benzylimidazole, or 1-ethyl-3-methylimidazole. Examples of the nitrile-based thermal initiator may include acrylonitrile, butadiene nitrile, or styrene nitrile. For example, the imidazole-based thermal initiator or the nitrile-based thermal initiator may have a structure represented by Formula 11.

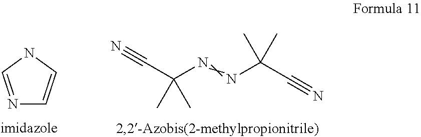

In one or more embodiments, the lens composition may include a crosslinking agent. In the lens composition excluding (e.g., not including) the solvent, the crosslinking agent may be in an amount of about 1 wt % to about 10 wt %. Examples of the crosslinking agent may include an aliphatic isocyanate crosslinking agent. If (e.g., when) the crosslinking agent implements a crosslinking structure with the polymer, for example, a polymer including two or more hydroxyl group-containing monomers, an adhesive having necessary or desired antistatic properties along with suitable low-speed and high-speed peeling strength may be implemented. As an example of the crosslinking agent, a crosslinking agent including an aliphatic cyclic isocyanate compound and/or an aliphatic non-cyclic isocyanate compound may be used. The term “aliphatic cyclic isocyanate compound” as used herein may refer to an isocyanate compound that includes a ring structure, but includes a ring structure not corresponding to an aromatic ring, and the term “aliphatic acyclic isocyanate compound” as used herein may refer to, for example, an aliphatic linear or branched isocyanate compound. Examples of the aliphatic cyclic isocyanate compound may include an isocyanate compound, such as isophorone diisocyanate, methylene dicyclohexyl diisocyanate, or cyclohexane diisocyanate, derivatives, such as dimers or trimers thereof, or a reactant of any of the materials as described herein with a polyol (e.g., trimethylolpropane). Examples of the aliphatic acyclic isocyanate compound may include an alkylene diisocyanate compound having 1 to 20 carbon atoms, 1 to 16 carbon atoms, 1 to 12 carbon atoms, or 1 to 8 carbon atoms, such as hexamethylene diisocyanate, derivatives thereof, such as dimers or trimers, or a reactant of any of the materials as described herein with a polyol (e.g. trimethylolpropane), but embodiments of the present disclosure are not limited thereto. In one or more embodiments, crosslinking agents that are generally available or generally used may be used together. Examples of the crosslinking agent may include an epoxy crosslinking agent, such as ethylene glycol diglycidyl ether, triglycidyl ether, trimethylolpropane triglycidyl ether, N,N,N′,N′-tetraglycidyl ethylenediamine, or glycerin diglycidyl ether, an aziridine crosslinker, such as N,N′-toluene-2,4-bis(1-aziridinecarboxamide), N,N′-diphenylmethane-4,4′-bis(1-aziridinecarboxamide), triethylene melamine, bisisopropyl-1-(2-methylaziridine), or tri-1-aziridinylphosphine oxide, or a metal chelate crosslinking agent that is a compound in which a multivalent metal such as aluminum, iron, zinc, tin, titanium, antimony, magnesium, and/or vanadium is coordinated to acetylacetone, ethyl acetoacetate, and/or the like. For example, the crosslinking agent may have a structure represented by Formula 12.

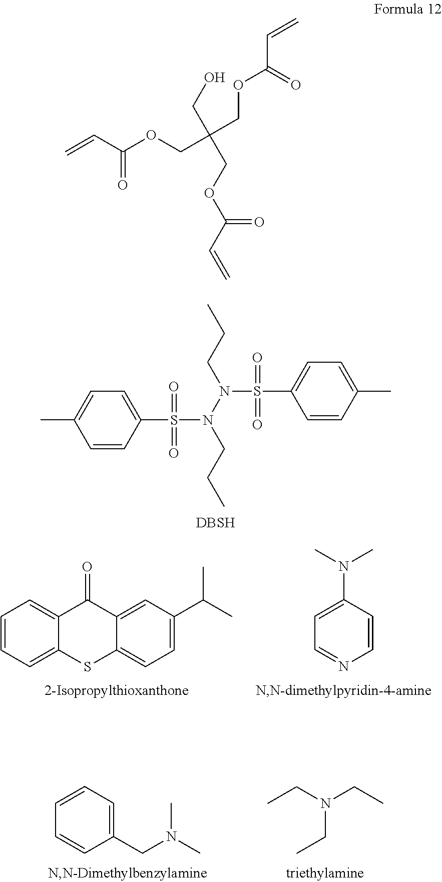

In one or more embodiments, the lens composition may include a solvent. If (e.g., when) the total weight of the lens composition including the solvent is 100 wt %, the solvent may be in an amount of about 60 wt % to about 90 wt %. Examples of the solvent may be selected from among propylene glycol monomethyl ether (PGME), ethylene glycol monomethyl ether acetate (PGMEA), propylene glycol monomethyl ether acetate, propylene glycol monoethyl ether acetate, diethylene glycol dimethyl ether, cyclohexanone, 2-heptanone, 3-heptanone, 2-hydroxyethylpropionate, 3-methyl-3-methoxybutylpropionate, ethyl-3-methoxypropionate, methyl-3-ethoxypropionate, ethyl-3-ethoxypropionate, butyl acetate, amyl permate, isoamyl acetate, isobutyl acetate, butyl propionate, isopropyl butyrate, ethyl butyrate, butyl butyrate, ethyl pyruvate, γ-butyrol acetate, methyl ethyl ketone, methyl cellosolve, ethyl cellosolve, ethylene glycol dimethyl ether, ethylene glycol diethyl ether, propylene glycol dimethyl ether, propylene glycol diethyl ether, diethylene glycol diethyl ether, diethylene glycol methyl ethyl ether, 2-ethoxy propanol, 2-methoxy propanol, 3-methoxy butanol, cyclohexanone, cyclopentanone, 3-methoxybutyl acetate, ethyl 3-ethoxypropionate, ethyl cellosolve acetate, methyl cellosolve acetate, butyl acetate, ethyl acetate, propyl acetate, and dipropylene glycol monomethyl ether.

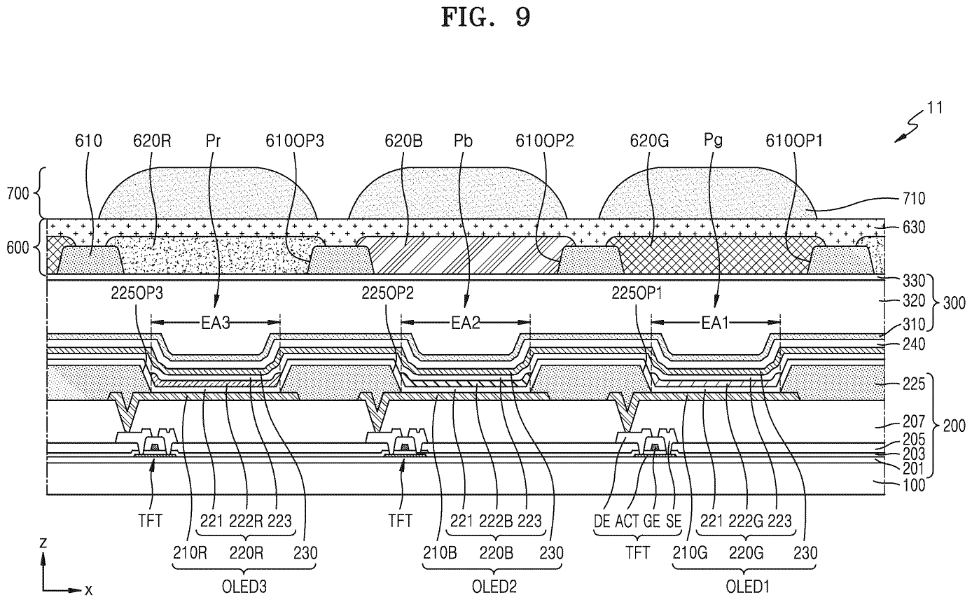

FIGS. 9 to 11 are cross-sectional views schematically illustrating a portion of a display panel 11 according to one or more embodiments.

Referring to FIG. 9, the display panel 11 may include a substrate 100, a display layer 200, an encapsulation layer 300, a functional layer 600, a lens layer 700, and a cover window 800.

The display panel 11 may include a plurality of sub-pixels in a display area (see DA of FIG. 5). Each of the sub-pixels may be configured or provided to emit red light, green light, or blue light. The sub-pixels may include sub-pixels configured or provided to emit different colors, for example, a first color sub-pixel, a second color sub-pixel, and a third color sub-pixel. Each of the first color sub-pixel, the second color sub-pixel, and the third color sub-pixel may be provided in plurality. In one or more embodiments, the first color sub-pixel may be a green sub-pixel Pg configured or provided to emit green light, the second color sub-pixel may be a blue sub-pixel Pb configured or provided to emit blue light, and the third color sub-pixel may be a red sub-pixel Pr configured or provided to emit red light.

The display layer 200 may be on the substrate 100. The substrate 100 may be, for example, a glass substrate.

The display layer 200 may include a sub-pixel circuit layer and a light-emitting diode layer. The sub-pixel circuit layer may include thin-film transistors TFT and may include insulating (e.g., electrically insulating) layers, such as a buffer layer 201, a gate insulating layer 203, an interlayer insulating layer 205, and a planarization layer 207.

The buffer layer 201 may be on the substrate 100. The buffer layer 201 may reduce or prevent infiltration of foreign material, moisture, and/or ambient air from below the substrate 100 and may provide a flat (e.g., substantially flat) surface on the substrate 100. The buffer layer 201 may include an inorganic material, such as an oxide or a nitride, an organic material, or an organic/inorganic composite material and may have a single-layer structure or a multilayer structure including an inorganic material and an organic material. A barrier layer that prevents infiltration of ambient air (or reduces a degree or occurrence of infiltration of ambient air) may be further included between the substrate 100 and the buffer layer 201. For example, the buffer layer 201 may include silicon oxide and/or silicon nitride.

The thin-film transistor TFT may be on the buffer layer 201. The thin-film transistor TFT may include a semiconductor layer ACT, a gate electrode GE, a source electrode SE, and a drain electrode DE. The thin-film transistor TFT may be connected to an organic light-emitting diode and configured or provided to drive the organic light-emitting diode.

The semiconductor layer ACT may be on the buffer layer 201. The semiconductor layer ACT may include polysilicon and/or amorphous (e.g., non-crystalline) silicon. In one or more embodiments, the semiconductor layer ACT may include an oxide of at least one selected from among indium (In), gallium (Ga), tin (Sn), zirconium (Zr), vanadium (V), hafnium (Hf), cadmium (Cd), germanium (Ge), chromium (Cr), titanium (Ti), and zinc (Zn). The semiconductor layer ACT may include a channel region, and a source region and a drain region doped with impurities.

Each of the gate electrode GE, the source electrode SE, and the drain electrode DE may include one or more suitable conductive (e.g., electrically conductive) materials. In one or more embodiments, the gate electrode GE may include at least one of molybdenum (Mo), aluminum (Al), copper (Cu), or titanium (Ti). For example, the gate electrode GE may be a single molybdenum (Mo) layer or may have a three-layer structure including a molybdenum (Mo) layer, an aluminum (Al) layer, and a molybdenum (Mo) layer. In one or more embodiments, each of the source electrode SE and the drain electrode DE may include at least one material selected from among copper (Cu), titanium (Ti), and aluminum (Al). For example, each of the source electrode SE and the drain electrode DE may have a three-layer structure including a titanium (Ti) layer, an aluminum (Al) layer, and a titanium (Ti) layer.

To ensure insulation (e.g., electrical insulation) between the semiconductor layer ACT and the gate electrode GE, the gate insulating layer 203 may be between the semiconductor layer ACT and the gate electrode GE. The interlayer insulating layer 205 may be on the gate electrode GE, and the source electrode SE and the drain electrode DE may be on the interlayer insulating layer 205.

Each of the gate insulating layer 203 and the interlayer insulating layer 205 may include an inorganic material, such as silicon oxide, silicon nitride, and/or silicon oxynitride. Each of the gate insulating layer 203 and the interlayer insulating layer 205 may be formed or provided by, for example, chemical vapor deposition (CVD) and/or atomic layer deposition (ALD).

The planarization layer 207 may be on the thin-film transistor TFT. To provide a flat (e.g., substantially flat) top surface, after the planarization layer 207 is formed or provided, chemical mechanical polishing may be performed on the top surface of the planarization layer 207. The planarization layer 207 may include a general-purpose polymer (e.g., photosensitive polyimide, polyimide, polystyrene (PS), polycarbonate (PC), benzocyclobutene (BCB), hexamethyldisiloxane (HMDSO), polymethylmethacrylate (PMMA), and/or the like), polymer derivatives having a phenol group, an acrylic-based polymer, an imide-based polymer, an aryl ether-based polymer, an amide-based polymer, a fluorine-based polymer, a p-xylene-based polymer, or a vinyl alcohol-based polymer. In FIG. 9, the planarization layer 207 is illustrated as a single layer, but in one or more embodiments, the planarization layer 207 may be a multilayer. Sub-pixel electrodes 210G, 210B, and 210R of first to third organic light-emitting diodes OLED1, OLED2, and OLED3 may be electrically connected to the thin-film transistors TFT through contact holes of the planarization layer 207, respectively.

The light-emitting diode layer may be on the sub-pixel circuit layer. In one or more embodiments, the light-emitting diode layer may include the first to third organic light-emitting diodes OLED1, OLED2, and OLED3 and a bank layer 225.

The first to third organic light-emitting diodes OLED1, OLED2, and OLED3 may be on the sub-pixel circuit layer. The first organic light-emitting diode OLED1 may include a stacked structure of the sub-pixel electrode 210G, an intermediate layer 220G, and an opposite electrode 230, wherein the intermediate layer 220G may include a first common layer 221, an emission layer 222G, and a second common layer 223. The second organic light-emitting diode OLED2 may include a stacked structure of the sub-pixel electrode 210B, an intermediate layer 220B, and the opposite electrode 230, wherein the intermediate layer 220B may include the first common layer 221, an emission layer 222B, and the second common layer 223. The third organic light-emitting diode OLED3 may include a stacked structure of the sub-pixel electrode 210R, an intermediate layer 220R, and the opposite electrode 230, wherein the intermediate layer 220R may include the first common layer 221, an emission layer 222R, and the second common layer 223.

The sub-pixel electrodes 210G, 210B, and 210R may be on the planarization layer 207. The sub-pixel electrodes 210G, 210B, and 210R may be spaced and/or apart (e.g., spaced apart or separated) from each other.

Each of the sub-pixel electrodes 210G, 210B, and 210R may be a reflection electrode. Each of the sub-pixel electrodes 210G, 210B, and 210R may include a reflection layer and a transparent electrode layer or a semitransparent electrode layer on the reflection layer. The reflection layer may include silver (Ag), magnesium (Mg), aluminum (Al), platinum (Pt), palladium (Pd), gold (Au), nickel (Ni), neodymium (Nd), iridium (Ir), chromium (Cr), or any compound thereof. The transparent electrode layer or the semitransparent electrode layer may include at least one material selected from among indium tin oxide (ITO), indium zinc oxide (IZO), zinc oxide (e.g., ZnO), indium oxide (e.g., In₂O₃), indium gallium oxide (IGO), or aluminum zinc oxide (AZO).

The bank layer 225 may be on the sub-pixel electrodes 210G, 210B, and 210R. The bank layer 225 may have first to third lower openings 2250P1, 2250P2, and 22250P3 respectively overlapping the sub-pixel electrodes 210G, 210B, and 210R and exposing the central portions of the sub-pixel electrodes 210G, 210B, and 210R. The bank layer 225 may cover the edges of the sub-pixel electrodes 210G, 210B, and 210R and may prevent an electric arc and/or the like from occurring (or reduce a degree to or occurrence of which an electric arc and/or the like occurs) on the edges of the sub-pixel electrodes 210G, 210B, and 210R by increasing the distance between the edge of each of the sub-pixels 210G, 210B, and 210R and the opposite electrode 230.

The first to third lower openings 2250P1, 2250P2, and 2250P3 of the bank layer 225 may respectively define first to third emission areas EA1, EA2, and EA3 of the first to third organic light-emitting diodes OLED1, OLED2, and OLED3 in each sub-pixel. As illustrated in FIG. 9, the bank layer 225 may include the first lower opening 2250P1 defining the first emission area EA1 of the first organic light-emitting diode OLED1 of the first color sub-pixel. In one or more embodiments, the bank layer 225 may include the second lower opening 2250P2 defining the second emission area EA2 of the second organic light-emitting diode OLED2 of the second color sub-pixel and may include the third lower opening 2250P3 defining the third light-emitting area EA3 of the third organic light-emitting diode OLED3 of the third color sub-pixel.

The bank layer 225 may include an organic insulating (e.g., electrically insulating) material. In one or more embodiments, the bank layer 225 may include an inorganic insulating (e.g., electrically insulating) material, such as silicon nitride or silicon oxide. In one or more embodiments, the bank layer 225 may include an organic insulating (e.g., electrically insulating) material and an inorganic insulating (e.g., electrically insulating) material.

In one or more embodiments, the bank layer 225 may include a light-blocking material. For example, the light-blocking material of the bank layer 225 may be black. The light-blocking material may include carbon black, carbon nanotubes, a resin and/or a paste including black dye, metal particles (e.g., nickel, aluminum, molybdenum, and any alloy thereof), metal oxide particles, and/or metal nitride particles. If (e.g., when) the bank layer 225 includes a light-blocking material, the reflection of external light (e.g., a degree or occurrence of the reflection of external light) due to the metal structures below the bank layer 225 may be reduced.

The intermediate layer may be on the sub-pixel electrodes 210G, 210B, and 210R and the bank layer 225. As described in one or more embodiments, the intermediate layer may include the first common layer 221, the emission layer, and the second common layer 223.

The emission layers 222G, 222B, and 222R may be respectively disposed or provided inside the first to third lower openings 2250P1, 2250P2, and 2250P3 of the bank layer 225. Each of the emission layers 222G, 222B, and 222R may be an organic material including a fluorescent material and/or a phosphorescent material capable of emitting red light, green light, or blue light. The organic material as described herein may include a low molecular weight organic material and/or a high molecular weight organic material.

The first common layer 221 and the second common layer 223 may be respectively disposed or provided below and above the emission layer. For example, the first common layer 221 may include a hole transport layer (HTL) or may include an HTL and a hole injection layer (HIL). For example, the second common layer 223 may include an electron transport layer (ETL) or may include an ETL and an electron injection layer (EIL). In one or more embodiments, the second common layer 223 may not be provided.

While the emission layers are disposed or provided for each sub-pixel to correspond to the first to third lower openings 2250P1, 2250P2, and 2250P3 of the bank layer 225, the first common layer 221 and the second common layer 223 may be integrally formed or provided to completely (e.g., substantially completely) cover the substrate 100. For example, the first common layer 221 and the second common layer 223 may be integrally formed or provided to completely (e.g., substantially completely) cover the display area DA of the substrate 100.

The opposite electrode 230 may be a cathode that is an electron injection electrode. The opposite electrode 230 may include a conductive (e.g., electrically conductive) material having a low work function. For example, the opposite electrode 230 may include a (semi)transparent layer including silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), or any alloy thereof. In one or more embodiments, the opposite electrode 230 may further include a layer including ITO, IZO, ZnO, and/or In₂O₃ on the (semi)transparent layer including the material as described herein.

In one or more embodiments, a capping layer 240 may be further disposed or provided on the display layer 200. The capping layer 240 may be on the first to third organic light-emitting diodes OLED1, OLED2, and OLED3. In one or more embodiments, the capping layer 240 may improve or enhance the light emission efficiency of the first to third organic light-emitting diodes OLED1, OLED2, and OLED3 by the principle of constructive interference.

The capping layer 240 may be an organic capping layer including an organic material, an inorganic capping layer including an inorganic material, or a composite capping layer including an organic material and an inorganic material. For example, the capping layer 240 may include a carbocyclic compound, a heterocyclic compound, an amine group-containing compound, porphine derivatives, phthalocyanine derivatives, naphthalocyanine derivatives, an alkali metal complex, an alkaline earth metal complex, or any combination thereof. The carbocyclic compound, the heterocyclic compound, and the amine group-containing compound may be optionally substituted with a substituent including oxygen (O), nitrogen (N), sulfur (S), selenium (Se), silicon (Si), fluorine (F), chlorine (CI), bromine (Br), iodine (I), or any combination thereof.

The encapsulation layer 300 may be on the capping layer 240. The encapsulation layer 300 may include at least one inorganic encapsulation layer and at least one organic encapsulation layer. For example, as illustrated in FIG. 9, the encapsulation layer 300 may include a first inorganic encapsulation layer 310, an organic encapsulation layer 320, and a second inorganic encapsulation layer 330, which are sequentially stacked in this stated order.

The first inorganic encapsulation layer 310 and the second inorganic encapsulation layer 330 may each include an inorganic insulating (e.g., electrically insulating) material, such as silicon oxide, silicon nitride, silicon oxynitride, aluminum oxide, titanium oxide, tantalum oxide, hafnium oxide, or zinc oxide. The first inorganic encapsulation layer 310 and the second inorganic encapsulation layer 330 may each have a single-layer structure or a multilayer structure including the inorganic insulating material as described herein.

The organic encapsulation layer 320 may relieve internal stress of the first inorganic encapsulation layer 310 and/or the second inorganic encapsulation layer 330. The organic encapsulation layer 320 may include a polymer-based material. For example, the organic encapsulation layer 320 may include polyethylene terephthalate, polyethylene naphthalate, polycarbonate, polyimide, polyethylene sulfonate, polyoxymethylene, polyarylate, hexamethyldisiloxane, an acrylic resin (e.g., polymethylmethacrylate, polyacrylic acid, and/or the like), or any combination thereof.

The encapsulation layer 300 may have a multilayer structure including the first inorganic encapsulation layer 310, the organic encapsulation layer 320, and the second inorganic encapsulation layer 330. In this case, even if (e.g., when) cracks occur in the encapsulation layer 300, the cracks may not propagate between the first inorganic encapsulation layer 310 and the organic encapsulation layer 320 or between the organic encapsulation layer 320 and the second inorganic encapsulation layer 330. The encapsulation layer 300 may prevent infiltration of ambient moisture and/or oxygen into the display area DA (or reduce a degree or occurrence of infiltration of ambient moisture and/or oxygen into the display area DA).

The functional layer 600 may be on the encapsulation layer 300. Referring to FIG. 9, the functional layer 600 may include a light blocking layer 610 and a plurality of color filters. In one or more embodiments, the functional layer 600 may include first to third color filters 620G, 620B, and 620R of different colors respectively corresponding to the first to third organic light-emitting diodes OLED1, OLED2, and OLED3. Each of the first to third color filters 620G, 620B, and 620R may be provided in plurality.

The light blocking layer 610 may have first to third upper openings 6100P1, 6100P2, and 6100P3 respectively corresponding to the first to third color sub-pixels. The light blocking layer 610 may include the first upper opening 6100P1 corresponding to the first emission area EA1, the second upper opening 6100P2 corresponding to the second emission area EA2, and the third upper opening 6100P3 corresponding to the third emission area EA3. Pieces of light emitted from the first to third organic light-emitting diodes OLED1, OLED2, and OLED3 may be respectively emitted to the outside through the first to third upper openings 610OP1, 6100P2, and 6100P3 of the light blocking layer 610.

The first upper opening 6100P1 of the light blocking layer 610 may overlap the first lower opening 2250P1 of the bank layer 225, the second upper opening 6100P2 may overlap the second lower opening 2250P2 of the bank layer 225, and the third upper opening 6100P3 may overlap the third lower opening 2250P3 of the bank layer 225.

As used herein, the width (or size) of each sub-pixel may refer to the width (or size) of the emission area of the organic light-emitting diode implementing each sub-pixel, and the width (or size) of the emission area may be defined by the width (or size) of the lower opening provided in the bank layer 225.

In one or more embodiments, the width (or size) of each of the first to third upper openings 610OP1, 6100P2, and 6100P3 of the light blocking layer 610 may be greater than the width (or size) of the corresponding sub-pixel among the first to third color sub-pixels. For example, the width (or size) of each of the first to third upper openings 610OP1, 6100P2, and 6100P3 of the light blocking layer 610 may be greater than the width (or size) of each of the first to third lower openings 2250P1, 2250P2, and 2250P3 of the bank layer 225.

In one or more embodiments, the width (or size) of each of the first to third upper openings 610OP1, 6100P2, and 6100P3 of the light blocking layer 610 may be substantially equal to the width (or size) of the corresponding sub-pixel among the first to third color sub-pixels. For example, the width (or size) of each of the first to third upper openings 610OP1, 6100P2, and 6100P3 of the light blocking layer 610 may be substantially equal to the width (or size) of each of the first to third lower openings 2250P1, 2250P2, and 2250P3 of the bank layer 225.

The light blocking layer 610 may include an organic insulating (e.g., electrically insulating) material. In one or more embodiments, the light blocking layer 610 may include an inorganic insulating (e.g., electrically insulating) material, such as silicon nitride or silicon oxide. In one or more embodiments, the light blocking layer 610 may include an organic insulating (e.g., electrically insulating) material and an inorganic insulating (e.g., electrically insulating) material.

In one or more embodiments, the light blocking layer 610 may include a light-blocking material. For example, the light-blocking material of the light blocking layer 610 may be black. The light-blocking material may include carbon black, carbon nanotubes, a resin and/or a paste including black dye, metal particles (e.g., nickel, aluminum, molybdenum, and any alloy thereof), metal oxide particles, and/or metal nitride particles. If (e.g., when) the light blocking layer 610 includes a light-blocking material, the reflection of external light (or a degree or occurrence of the reflection of external light) due to the metal structures below the light blocking layer 610 may be reduced.

The first to third color filters 620G, 620B, and 620R may be respectively disposed or provided in the first to third upper openings 610OP1, 6100P2, and 6100P3 of the light blocking layer 610. The first to third color filters 620G, 620B, and 620R may have colors respectively corresponding to pieces of light emitted from the first to third emission areas EA1, EA2, and EA3. In one or more embodiments, if (e.g., when) green light is emitted from the first emission area EA1, the first color filter 620G may be a green color filter; if (e.g., when) blue light is emitted from the second emission area EA2, the second color filter 620B may be a blue color filter; and if (e.g., when) red light is emitted from the third emission area EA3, the third color filter 620R may be a red color filter.

The functional layer 600 may further include an overcoat layer 630. The overcoat layer 630 may be on the light blocking layer 610 and/or the first to third color filters 620G, 620B, and 620R. The overcoat layer 630 may planarize the upper surfaces of the light blocking layer 610 and/or the first to third color filters 620G, 620B, and 620R. The overcoat layer 630 may be a colorless, light-transmitting layer that does not have a color in a visible light band. The overcoat layer 630 may include a colorless, light-transmitting organic material, such as acrylic-based resin.

The lens layer 700 may be on the functional layer 600. For example, the lens layer 700 may be on the overcoat layer 630. In one or more embodiments, if (e.g., when) the display panel 11 does not include the functional layer 600 or does not need to or is not desired to include the functional layer 600, the lens layer 700 may be on the encapsulation layer 300.

The lens layer 700 may prevent glare (or reduce a degree or occurrence of glare) by reducing light reflection (or reducing a degree or occurrence of light reflection). In one or more embodiments, the lens layer 700 may include the lens composition as described in one or more embodiments and may be formed or provided by patterning the lens composition into a lens shape on the functional layer 600.

The lens layer 700 may include a plurality of lens parts 710 that protrude convexly toward the opposite side of the substrate 100. The lens parts 710 may each have a convex lens shape. The lens parts 710 may be on the functional layer 600, for example, the overcoat layer 630. The lens parts 710 may be formed or provided to protrude from the upper surface of the overcoat layer 630.

In one or more embodiments, the lens layer 700, e.g., the lens parts 710, may include the lens composition. The lens composition may include a base resin including a cardo-based resin having a cardo-based moiety structure and having a refractive index of about 1.5 or more, an acid anhydride-based compound, a silane-based coupling compound, an acrylic-based acidic compound including an acrylic group, an oxime-based photoinitiator, and a solvent. In one or more cases, the lens composition may further include at least one selected from among a urethane-based additive, an antioxidant, an amine-based co-initiator, a thermal initiator, and a crosslinking agent. As described in one or more embodiments, because the lens composition includes a cardo-based resin having a high refractive index of about 1.5 or more as the base resin, the refractive index of the lens composition may be improved or enhanced. In one or more embodiments, the refractive index of the lens composition may be in a range of about 1.5 to about 1.7.

In one or more embodiments, if (e.g., when) the total amount of the lens composition excluding (e.g., not including) the solvent is 100 wt %, the lens composition may include about 20 wt % to about 50 wt % of the cardo-based resin, about 10 wt % to about 50 wt % of the acid anhydride-based compound, about 1 wt % to about 10 wt % of the silane-based coupling compound, about 10 wt % to about 30 wt % of the acidic compound, and about 0.5 wt % to about 10 wt % of the oxime-based photoinitiator. The solvent may be in an amount of about 60 wt % to about 90 wt % of the total lens composition. Furthermore, in one or more embodiments, if (e.g., when) the total amount of the lens composition excluding (e.g., not including) the solvent is 100 wt %, the lens composition may further include at least one selected from among about 10 wt % to about 30 wt % of the urethane-based additive, about 0.1 wt % to about 3 wt % of the antioxidant, about 0.5 wt % to about 10 wt % of the amine-based co-initiator, about 0.001 wt % to about 5 wt % of the thermal initiator, and about 1 wt % to about 10 wt % of the crosslinking agent.

As described in one or more embodiments, because the lens parts 710 are formed or provided by utilizing the lens composition according to one or more embodiments, the adhesion to the lower layer may be improved or enhanced to prevent film lifting (or reduce a degree or occurrence of film lifting), the optical properties may be improved or enhanced to enhance the resolution of the display panel 11, and the reflow phenomenon may be reduced if (e.g., when) patterning the lens parts 710, so that (e.g., such that) excellent or suitable patterning properties may be achieved. In one or more embodiments, because the lens composition according to one or more embodiments has the materials and composition as described in one or more embodiments, the lens parts 710 may be formed or provided by directly applying the lens composition onto the glass substrate 100 and then performing patterning, so-called direct patterning, thereon without utilizing a photoresist (PR), thereby simplifying the process, lowering the unit cost, and dramatically increasing the productivity. However, embodiments of the present disclosure are not necessarily limited thereto, and a photolithography and/or an imprinting method utilizing a PR may be used as the method of forming or providing the lens parts 710 of the lens composition.

In one or more embodiments, the lens layer 700 may include the lens parts 710. The lens parts 710 may be spaced and/or apart (e.g., spaced apart or separated) from each other to correspond to a plurality of light-emitting elements, for example, the first to third organic light-emitting diodes OLED1, OLED2, and OLED3. The lens parts 710 may include a first lens part 711 and a second lens part 712 adjacent to each other, and a distance d between the first lens part 711 and the second lens part 712 may be in a range of about 1.5 μm to about 3.5 μm, and, for example, about 1.5 μm to about 2.5 μm.

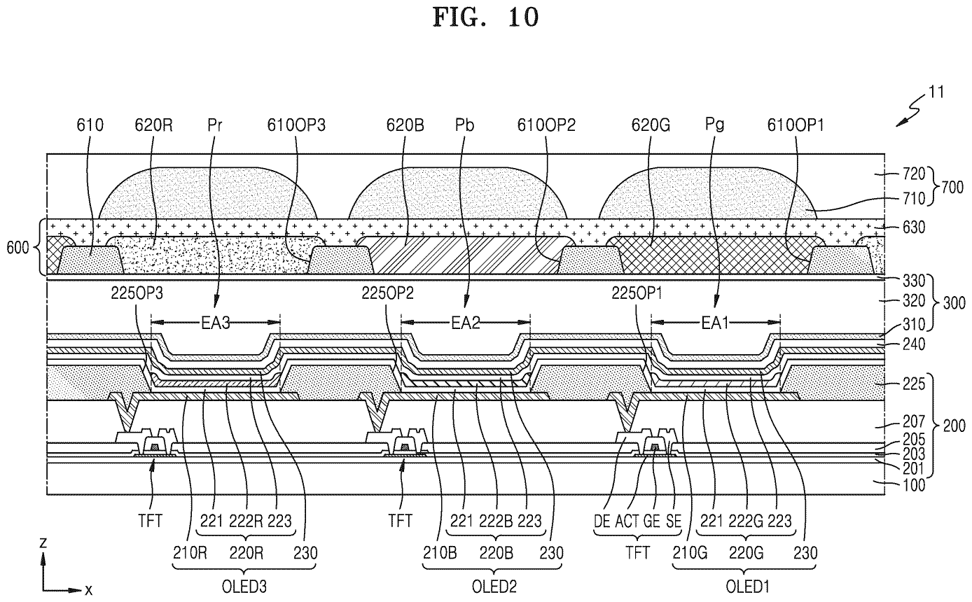

Referring to FIG. 10, in addition to those described with reference to FIG. 9, the lens layer 700 may further include an insulating layer 720. The insulating layer 720 may be on the lens parts 710 and cover the lens parts 710, and the upper surface of the insulating layer 720 may be substantially flat. The insulating layer 720 may be disposed or provided to fill a space between the lens parts 710 spaced and/or apart (e.g., spaced apart or separated) from each other, and may be in direct contact with the upper surfaces of the lens parts 710. The insulating layer 720 may include an organic insulating (e.g., electrically insulating) material, such as an acrylic-based resin, an epoxy-based resin, polyimide, and/or polyethylene. In one or more embodiments, the insulating layer 720 may include polydiarylsiloxane, methyltrimethoxysilane, tetramethoxysilane, and/or the like. In one or more embodiments, the insulating layer 720 may include an acrylic-based organic material and/or a siloxane-based organic material. In the insulating layer 720, dispersion particles for high refractive index, for example, metal oxide particles, such as zinc oxide (e.g., ZnOₓ, wherein 0<x≤2; e.g., ZnO or ZnO₂), titanium oxide (e.g., TiO₂), or zirconium oxide (e.g., ZrO₂), may be dispersed in the organic insulating material as described in one or more embodiments.

The refractive indices of the insulating layer 720 and the lens parts 710 including the lens composition as described in one or more embodiments may be different from each other. For example, the insulating layer 720 may be a low-refractive-index layer. A first refractive index (n1) of the lens parts 710 may be greater than a second refractive index (n2) of the insulating layer 720. The first refractive index (n1) of the lens parts 710 may be, for example, about 1.5 or more and about 1.7 or less (e.g., 1.5≤n1≤1.7). The second refractive index (n2) of the insulating layer 720 may be, for example, about 1.3 or more and less than 1.6 (e.g., 1.3≤n2<1.6). In one or more embodiments, the first refractive index of the lens parts 710 may be in a range of about 1.6 to about 1.7, and the second refractive index of the insulating layer 720 may be in a range of about 1.3 to about 1.4. As described in one or more embodiments, the light output efficiency of the display panel 11, for example, the front efficiency, may be further improved or enhanced due to the difference in structure and/or refractive index of the plurality of lens parts 710 and the insulating layer 720 included in the lens layer 700.

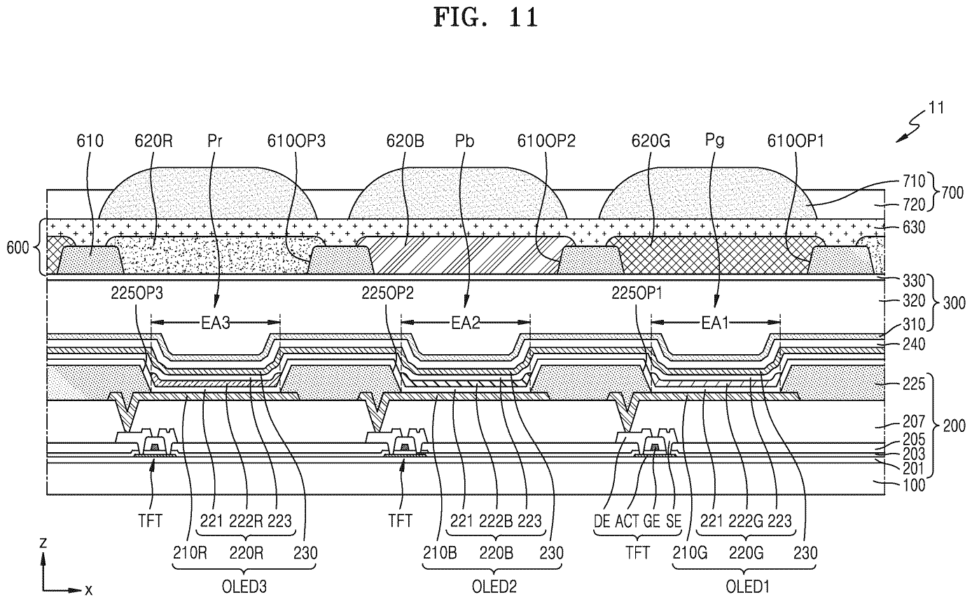

Referring to FIG. 11, unlike those described with reference to FIG. 10, the insulating layer 720 may be between the lens parts 710 spaced and/or apart (e.g., spaced apart or separated) from each other. For example, the insulating layer 720 of FIG. 11 may be between the lens parts 710 while exposing at least a portion of the upper surfaces of the lens parts 710, instead of completely (e.g., substantially completely) covering the upper surfaces of the lens parts 710.

As a process sequence, in FIG. 11, patterns of the lens parts 710 may be on the functional layer 600, and then, the insulating layer 720 may be formed or provided to fill the space between the lens parts 710. In one or more embodiments, the insulating layer 720 having openings may be on the functional layer 600, and then, the lens parts 710 may be formed or provided by patterning to correspond to the openings. As described in one or more embodiments, because the insulating layer 720, which is the low-refractive-index layer, is between the lens parts 710 spaced and/or apart (e.g., spaced apart or separated) from each other, the insulating layer 720 may act as a dam that prevents reflow (or reduces a degree or occurrence of reflow) of the lens parts 710, and the light output efficiency of the display panel 11, for example, the front efficiency, may be further improved or enhanced due to the difference in structure and/or refractive index of the lens parts 710 and the insulating layer 720.

In one or more embodiments, a cover window may be on the lens layer 700. In one or more embodiments, the cover window may be attached to the lens layer 700 by an adhesive layer. In one or more embodiments, the cover window may not be provided.

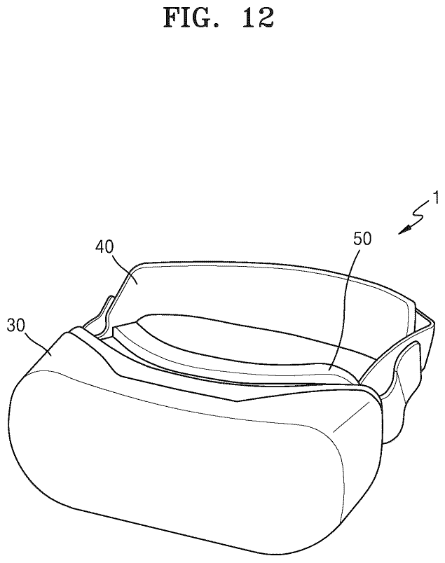

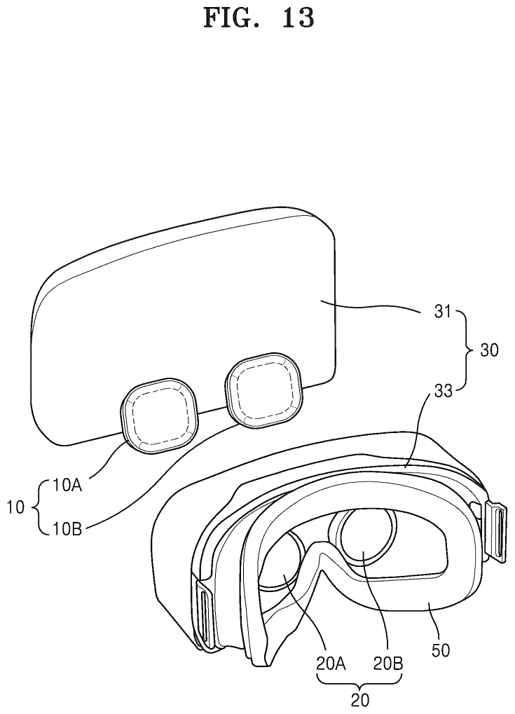

FIG. 12 is a perspective view schematically illustrating an electronic device 10 according to one or more embodiments. FIG. 13 is an exploded view schematically illustrating the electronic device 10 according to one or more embodiments. The electronic device 10 of FIGS. 12 and 13 may include the display panel 11 described with reference to FIGS. 1 to 11.

Referring to FIGS. 12 and 13, the electronic device 10 may be worn on a head of a user. The electronic device 10 may provide images with or without blocking actual peripheral vision of the user. The user wearing the electronic device 10 may easily immerse himself/herself in augmented reality or virtual reality. The electronic device 10 may include the display panel 11, an optical part 20, a case part 30, a fixing part 40, and a cushion part 50.

The display panel 11 may be configured or provided to provide an image. The display panel 11 may be configured or provided to emit light to provide an image. The display panel 11 may be accommodated in the case part 30. In one or more embodiments, the electronic device 10 may include a plurality of display panels 11. For example, the electronic device 10 may include a first display panel 10A and a second display panel 10B. In this case, the first display panel 10A and the second display panel 10B may overlap a plurality of optical part 20. The first display panel 10A may be a left-eye display panel. The second display panel 10B may be a right-eye display panel. In one or more embodiments, the electronic device 10 may include a single display panel 11. In this case, the optical parts 20 may each overlap the single display panel 11.

The optical part 20 may be configured or provided to transmit light emitted from the display panel 11. The optical part 20 may be configured or provided to refract and/or reflect light emitted from the display panel 11. In one or more embodiments, the optical part 20 may be configured or provided to magnify an image provided from the display panel 11. The optical part 20 may be disposed or provided to be opposite to (e.g., face) the display panel 11. If (e.g., when) the user wears the electronic device 10, the optical part 20 may be between the user and the display panel 11. Accordingly, the user may perceive light emitted from the display panel 11 and refracted and/or reflected by the optical part 20. In one or more embodiments, the optical part 20 may include at least one of a lens or a mirror.

In one or more embodiments, the electronic device 10 may include a plurality of optical parts 20. For example, the electronic device 10 may include a first optical part 20A and a second optical part 20B. In this case, the first display panel 11A may be opposite to (e.g., face) the first optical part 20A. The second display panel 11B may be opposite to (e.g., face) the second optical part 20B. The first optical part 20A may be a left-eye optical part. The second optical part 20B may be a right-eye optical part. In one or more embodiments, the electronic device 10 may include a single optical part 20.

The case part 30 may accommodate the display panel 11 and the optical part 20. The case part 30 may have an internal space, and the display panel 11 and the optical part 20 may be in the internal space. The case part 30 may protect the display panel 11 and optical part 20 from external impact. In one or more embodiments, the case part 30 may be separated into a cover part 31 and a body part 33. In one or more embodiments, the cover part 31 and the body part 33 may be integrally provided as a single body. In one or more embodiments, the cover part 31 may be opaque. In one or more embodiments, the cover part 31 may be transparent (e.g., substantially transparent).

The case part 30 may support the curved display panel 11. For example, the display panel 11 may be fixed within the case part 30. Furthermore, the case part 30 may support the curved display panel 11 so that (e.g., such that) the shape of the curved display panel 11 is maintained.

The fixing part 40 may fix the case part 30 to the head of the user. Accordingly, the electronic device 10 may be worn on the head of the user. In one or more embodiments, the length of the fixing part 40 may be adjustable. For example, the length of the fixing part 40 may be adjustable according to the head circumference of the user.

The fixing part 40 may bring the electronic device 10 into close contact with the head of the user. In one or more embodiments, the fixing part 40 may be elastic. FIG. 12 illustrates that the fixing part 40 is a strap, but in one or more embodiments, the fixing part 40 may have one or more suitable forms, such as a helmet coupled to the case part 30 or a glasses frame connected to the case part 30. The fixing part 40 may be connected to the case part 30. In one or more embodiments, the fixing part 40 may be attachable to or detachable from the case part 30.

The cushion part 50 may improve or enhance the wearing comfort for the user. If (e.g., when) the user wears the electronic device 10, the cushion part 50 may be between the user and the case part 30. In one or more embodiments, the cushion part 50 may be attached to the case part 30. In one or more embodiments, the cushion part 50 may be detached from the case part 30. In one or more embodiments, the cushion part 50 may not be provided.

The cushion part 50 may include a material whose shape is freely deformable. For example, the cushion part 50 may include a polymer resin. For example, the cushion part 50 may include at least one of polyurethane, polycarbonate, polypropylene, or polyethylene. In one or more embodiments, the cushion part 50 may include a sponge formed or provided by foaming a rubber liquid, a urethane-based material, or an acrylic-based material.

According to one or more embodiments, the lens composition for improving or enhancing display quality and the display panel and the electronic device utilizing the lens composition may be implemented. The scope of the present disclosure is not limited to the embodiments as described in the detailed description of the present disclosure, but should be determined by the appended claims and equivalents thereof.

It should be understood that embodiments described herein should be considered in a descriptive sense only and not for purposes of limitation. Descriptions of features or aspects within each embodiment should generally be considered as available for other similar features or aspects in other embodiments. While the subject matter of the present disclosure has been described with reference to the drawings, it will be understood by those of ordinary skill in the art that one or more suitable changes in form and more details may be made therein without departing from the spirit and scope as defined by the following claims and equivalents thereof.

What is claimed is:

1. A display panel comprising:
a plurality of light-emitting elements on a glass substrate;
an encapsulation layer provided on the plurality of light-emitting elements and sealing the plurality of light-emitting elements; and
a lens layer provided on the encapsulation layer and comprising a plurality of lens parts spaced from each other,
wherein the lens layer comprises a lens composition comprising:
a base resin comprising a cardo-based resin having a cardo-based moiety structure and having a refractive index of 1.5 or more,
an acid anhydride-based compound,
a silane-based coupling compound,
an acidic compound, and
an oxime-based photoinitiator.

2. The display panel as claimed in claim 1, wherein a refractive index of the lens layer is in a range of 1.5 to 1.7.

3. The display panel as claimed in claim 1, wherein the base resin further comprises at least one of an acrylate-based monomer, an epoxy-based monomer, or an organic-inorganic composite material.

4. The display panel as claimed in claim 1, wherein the lens composition further comprises at least one of a urethane-based additive, an antioxidant, an amine-based co-initiator, or a thermal initiator.

5. The display panel as claimed in claim 1, wherein the lens composition further comprises a solvent, and when a total amount of the lens composition excluding the solvent is 100 wt %, the lens composition comprises:
20 wt % to 50 wt % of the cardo-based resin,
10 wt % to 50 wt % of the acid anhydride-based compound,
1 wt % to 10 wt % of the silane-based coupling compound,
10 wt % to 30 wt % of the acidic compound, and
0.5 wt % to 10 wt % of the oxime-based photoinitiator.

6. The display panel as claimed in claim 5, wherein the lens composition further comprises 10 wt % to 30 wt % of a urethane-based additive.

7. The display panel as claimed in claim 5, wherein the lens composition further comprises 0.1 wt % to 3 wt % of an antioxidant.

8. The display panel as claimed in claim 5, wherein the lens composition further comprises 0.5 wt % to 10 wt % of an amine-based co-initiator.

9. The display panel as claimed in claim 5, wherein the lens composition further comprises 0.001 wt % to 5 wt % of a thermal initiator.

10. The display panel as claimed in claim 1, wherein a distance between a first lens part and a second lens part adjacent to each other among the plurality of lens parts spaced from each other and respectively corresponding to the plurality of light-emitting elements is 1.5 μm to 2.5 μm.

11. The display panel as claimed in claim 10, wherein:
the lens layer further comprises an insulating layer provided on the plurality of lens parts and covering the plurality of lens parts, and
the insulating layer has a refractive index less than a refractive index of the plurality of lens parts.

12. The display panel as claimed in claim 10, wherein:
the lens layer further comprises an insulating layer between the plurality of lens parts spaced from each other, and
the insulating layer has a refractive index less than a refractive index of the lens layer.

13. A lens composition for use in a display panel comprising a light-emitting element, wherein the lens composition comprises a solvent, and when a total amount of the lens composition excluding the solvent is 100 wt %, the lens composition further comprises:
20 wt % to 50 wt % of a base resin comprising a cardo-based moiety having a refractive index of 1.5 or more,
10 wt % to 50 wt % of an acid anhydride-based compound,
1 wt % to 10 wt % of a silane-based coupling compound,
10 wt % to 30 wt % of an acidic compound, and
0.5 wt % to 10 wt % of an oxime-based photoinitiator.

14. The lens composition as claimed in claim 13, wherein a refractive index of the lens composition is in a range of 1.5 to 1.7.

15. The lens composition as claimed in claim 13, wherein the lens composition further comprises at least one of a urethane-based compound, an antioxidant, an amine-based co-initiator, or a thermal initiator.

16. The lens composition as claimed in claim 15, wherein:
the urethane-based compound is in a range of 10 wt % to 30 wt %,
the antioxidant is in a range of 0.1 wt % to 3 wt %,
the amine-based co-initiator is in a range of 0.5 wt % to 10 wt %, and
the thermal initiator is in a range of 0.001 wt % to 5 wt %.

17. The lens composition as claimed in claim 13, wherein the base resin further comprises at least one of an acrylate-based monomer, an epoxy-based monomer, or an organic-inorganic composite material.

18. The lens composition as claimed in claim 17, wherein:
the acrylate-based monomer is in a range of 1 wt % to 35 wt %, and
the epoxy-based monomer is in a range of 5 wt % to 15 wt %.

19. An electronic device comprising:
a processor; and
a display panel provided to be controlled by the processor,
wherein the display panel comprises:
a light-emitting element on a glass substrate;
an encapsulation layer provided on the light-emitting element and sealing the light-emitting element; and
a lens layer provided on the encapsulation layer and comprising a lens part provided to correspond to the light-emitting element,
wherein the lens layer comprises a lens composition, the lens composition comprising:
a base resin comprising a cardo-based resin having a cardo-based moiety structure and having a refractive index of 1.5 or more;
an acid anhydride-based compound;
a silane-based coupling compound;
an acidic compound;
an oxime-based photoinitiator; and
a crosslinking agent.

20. The electronic device as claimed in claim 19, wherein a refractive index of the lens composition is in a range of 1.5 to 1.7.
